(19) United States
(12) Patent Application Publication
(10) Pub. No.: US 2023/0295488 A1
(43) Pub. Date: Sep. 21, 2023

(54) Nanocrystalline preparation method, nanocrystalline, and optical film and light emitting device containing same

(71) Applicant: Najing Technology Corporation Limited, Hangzhou, Zhejiang (CN)

(72) Inventors: Baozhong HU, Hangzhou, Zhejiang (CN); Yuan GAO, Hangzhou, Zhejiang (CN); Guangxu LI, Hangzhou, Zhejiang (CN); Tao ZHAO, Hangzhou, Zhejiang (CN)

(21) Appl. No.: 18/017,084

(22) PCT Filed: Jul. 22, 2021
(86) PCT No.: PCT/CN2021/107864

§ 371 Date: Jan. 20, 2023

(30) Foreign Application Priority Data
Jul. 23, 2020 (CN) 202010716672.8
Jan. 29, 2021 (CN) 202110130341.0

(51) Int. Cl. C09K 11/02; C09K 11/88; H01L 33/50

(52) U.S. Cl. CPC C09K 11/025; C09K 11/883; H01L 33/502; B82Y 30/00

(57) ABSTRACT

Provided are a nanocrystalline, a preparation method and a composition, an optical film, and a light emitting device. The nanocrystalline comprises an initial nanocrystalline and a sacrificial shell layer coated outside of the initial nanocrystalline. The sacrificial shell layer comprises n sacrificial sub-layers sequentially coated outward from the initial nanocrystalline at the center. The n sacrificial sub-layers may be of the same material or different materials. If the nanocrystalline is etched, at least a portion of the sacrificial shell layer is gradually consumed during the etching process. The following are measured m times during the etching process: the fluorescence emission wavelength, the full width at half maximum, the quantum yield, and the absorbance under excitation of an excitation light of a certain wavelength are measured, wherein 0≤MAX_{PL}−MIN_{PL}≤10 nm, 0≤MAX_{FWHM}−MIN_{FWHM}≤10 nm, 80%≤MIN_{QY}/MAX_{QY}≤100%, and 80%≤MIN_{AB}/MAX_{AB}≤100%, and n and m are integers greater than or equal to 1.

The present application is a National Stage of International Patent Application No: PCT/CN2021/107864 filed on Jul. 22, 2021, which is herein incorporated by reference in their entirety.

### TECHNICAL FIELD

The present disclosure relates to the field of photoelectric technologies, and specifically, to a nanocrystalline preparation method, nanocrystalline, and an optical film and a light emitting device containing the same.

### BACKGROUND

In recent years, with the rapid development of a liquid crystal backlight technology, new technologies and new products were launched, which had advantages of being high in color gamut, high in brightness, long in service life, and energy-saving and environment-friendly. A high color gamut backlight can make screens of electronic products such as televisions, mobile phones and tablet computers had more vivid colors and higher degree of color reproducibility. Currently, a conventional LED backlight adopted the form of exciting YAG yellow phosphor powder by a blue light-emitting chip. Since the backlight lacks of a red light component, a color gamut value could only reach NTSC 65% to 72%. In order to further increase the color gamut value; technicians generally adopt the form of simultaneously exciting red phosphor powder and green phosphor powder by the blue light-emitting chip. However, since the Full Width at Half Maximum (FWHM) of the phosphor powder is relatively wide, the color gamut value of the backlight can only be increased to about NTSC 85% even if this method is adopted. As a novel nano fluorescent material, Quantum Dot (QD) has showed the characteristics of strong correlation between the sizes and optical properties of QD. Compared with a conventional fluorescent material, the QD has a series of unique optical properties of being adjustable in spectrum, narrow in FWHM of emission peak, large in Stokes shift and high in excitation efficiency, so that a packaging effect of high color gamut (≥NTSC 98%) might be easily realized, which had been widely concerned by the LED backlight industry.

In addition, the QD is nanoscale light-emitting nanocrystalline, has a high specific surface area, and is high in chemical reactivity and sensitive in external environment. Although the stability of the QD with a core-shell structure formed by coating a broad-band gap semiconductor material is greatly improved, but under strong blue light irradiation, the probability of the QD in an excited state is greatly increased, and it is easy to photochemically react with water and oxygen, resulting in oxidation etching of shell layer of the QD, changes in absorption and emission spectra of the QD, and reduction or even quenching of Quantum Yield (QY). In the prior art, the stability of the QD was improved by coating silica or metal oxide, but the space for stability improvement was limited. As oxides such as silica are in an amorphous state, there are many micropores on the surface, so that water and oxygen cannot be completely isolated. In addition, during the coating of the oxides, due to changes in the surface ligands of the QD, the QY is decreased, which does not facilitate commercial applications. Nowadays, in actual commercial application scenarios of the QD, for example, QD televisions such as Samsung and TCL, a barrier film is usually used to package the QD. The barrier film has excellent performance of isolating water and oxygen, and can delay photoetching of the QD, so that the service life of photoluminescence of the QD is maintained. However, the barrier film is relatively high in cost, so that the QD can only be applied to high-end display products at present.

### SUMMARY

The disclosure is intended to provide a nanocrystalline, including an initial nanocrystalline and a sacrificial shell layer coated outside of the initial nanocrystalline. The sacrificial shell layer includes n sacrificial sub-layers sequentially coated outward with the initial nanocrystalline as the center, and the n sacrificial sub-layers may be of the same material or different materials. If the nanocrystalline is etched, at least a portion of the sacrificial shell layer is gradually consumed during etching. Fluorescence emission peak wavelength, FWHM, QY, and absorbance under excitation of an excitation light with a certain wavelength are measured m times during the etching. A maximum fluorescence emission peak wavelength and a minimum fluorescence emission peak wavelength in measurement results of m times are respectively set to be MAX_{PL} and MIN_{PL}; a maximum FWHM and a minimum FWHM respectively are MAX_{FWHM} and MIN_{FWHM}; a maximum QY and a minimum QY respectively are MAX_{QY} and MIN_{QY}; and maximum absorbance and minimum absorbance respectively are MAX_{AB} and MIN_{AB}, where 0≤MAX_{PL}−MIN_{PL}≤10 nm, 0≤MAX_{FWHM}−MIN_{FWHM}≤10 nm, 80%≤MIN_{QY}/MAX_{QY}≤100%, and 80%≤MIN_{AB}/MAX_{AB}≤100%, and n and m are integers greater than or equal to 1.

Optionally, 0≤MAX_{PL}−MIN_{PL}≤5 nm, and 0≤MAX_{FWHM}−MIN_{FWHM}≤5 nm.

Optionally, m is an integer greater than or equal to 2. During the etching, a difference between the fluorescence emission peak wavelength of two adjacent measurements is [−2 nm, 2 nm]; a difference between the full width at half maximum of two adjacent measurements is [−2 nm, 2 nm]; a percentage change in QY between two adjacent measurements is [−10%, 10%]; and a percentage change in absorbance between two adjacent measurements is [−10%, 10%].

Optionally, a material of the sacrificial shell layer is selected from one or more of ZnN, ZnS, AlSb, ZnP, InP, AlS, PbS, HgS, AgS, ZnInS, ZnAlS, ZnSeS, CdSeS, CuInS, CuGaS, CuAlS, AgInS, AgAlS, AgGaS, ZnInP, ZnGaP, CdZnS, CdPbS, CdHgS, PbHgS, CdZnPbS, CdZnHgS, CdInZnS, CdAlZnS, CdSeZnS, AgInZnS, CuInZnS, AgGaZnS, CuGaZnS, CuZnSnS, CuAlZnS, CuCdZnS, MnS, ZnMnS, ZnPbS, WS, ZnWS, CoS, ZnCoS, NiS, ZnNiS, InS, SnS, and ZnSnS.

Optionally, a thickness of the sacrificial shell layer is 5-15 nm.

The disclosure further provides a method for preparing a nanocrystalline, including: S1, preparing an initial nanocrystalline; and S2, coating a sacrificial shell layer outside the initial nanocrystalline at one time or in steps, where the formed sacrificial shell layer includes n sacrificial sub-layers sequentially coated outward with the initial nanocrystalline as the center, respectively being the first sacrificial sub-layer, the second sacrificial sub-layer, . . . , the nth sacrificial sub-layer, and n is an integer greater than or equal to 1; an intermediate nanocrystalline with the first sacrificial sub-layer to the ith sacrificial sub-layer coated outside the initial nanocrystalline is denoted by an ith nanocrystalline, fluorescence emission peak wavelength of the ith nanocrystalline is PLᵢ, FWHM of the ith nanocrystalline is FWHMᵢ, QY of the ith nanocrystalline is QYᵢ, and absorbance under excitation of an excitation light with a certain wavelength is ABSᵢ. When i takes all integers of [1, n], a maximum fluorescence emission peak wavelength and a minimum fluorescence emission peak wavelength in PLᵢ are respectively recorded as MAX_{PL} and MIN_{PL}; a maximum FWHM and a minimum FWHM in the above FWHMᵢ are respectively recorded as MAX_{FWHM} and MIN_{FWHM}; a maximum QY and a minimum QY in the above QY, are respectively recorded as MAX_{QY} and MIN_{QY}; and maximum absorbance and minimum absorbance in the above ABSᵢ, are respectively recorded as MAX_{AB} and MIN_{AB}, and 0≤MAX_{PL}−MIN_{PL}≤10 nm, 0≤MAX_{FWHM}−MIN_{FWHM}≤10 nm, 80%≤MIN_{QY}/MAX_{QY}≤100%, and 80%≤MIN_{AB}/MAX_{AB}≤100%.

Optionally, 0≤MAX_{PL}−MIN_{PL}≤5 nm; and 0≤MAX_{FWHM}−MIN_{FWHM}≤5 nm.

Optionally, a difference between the fluorescence emission peak wavelength of the (i−1)th nanocrystalline and the ith nanocrystalline is [−2 nm, 2 nm]; a difference between the FWHM is [−2 nm, 2 nm]; a percentage change in the QY is [−10%, 10%]; and a percentage change in the absorbance is [−10%, 10%].

Optionally, the method for coating the ith sacrificial sub-layer in S2 includes: mixing the initial nanocrystalline or the (i−1)th nanocrystalline, one or more cationic precursors configured to form the ith sacrificial sub-layer, one or more anion precursors configured to form the ith sacrificial sub-layer, and a solvent for reaction, and obtaining the ith nanocrystalline coated with the ith sacrificial sub-layer after the reaction.

Optionally, the method for coating the ith sacrificial sub-layer in S2 includes: mixing the initial nanocrystalline or the (i−1)th nanocrystalline, one or more cationic precursors configured to form the ith sacrificial sub-layer, one or more anion precursors configured to form the ith sacrificial sub-layer, and a solvent for reaction for a certain period of time, then adding a doping agent containing a doping element to continue the reaction, and obtaining the ith nanocrystalline coated with the ith sacrificial sub-layer after the reaction. The doping element is preferably at least one of In, Al, Ga, Cd, Pb, Hg, Mn, Ni, Co, Cr, W, Ag, or Cu.

Optionally, the method for coating the ith sacrificial sub-layer in S2 includes: mixing the initial nanocrystalline or the (i−1)th nanocrystalline, one or more cationic precursors configured to form the ith sacrificial sub-layer, one or more anion precursors configured to form the ith sacrificial sub-layer, and a solvent in a container for reaction; when the fluorescence emission peak wavelength of products in the container was blue-shifted in two adjacent monitoring, adding a first cationic precursor to the container at least once; and when the fluorescence emission peak wavelength of the product in the container is red-shifted in two adjacent monitoring, adding a second cationic precursor to the container at least once, and obtaining the ith nanocrystalline coated with the ith sacrificial sub-layer after the reaction.

Optionally, first cation of the first cationic precursor is able to red-shift the fluorescence emission peak wavelength of the nanocrystalline. Second cation of the second cationic precursor is able to blue-shift the fluorescence emission peak wavelength of the nanocrystalline. Preferably, the first cationic precursor is a cadmium precursor, an indium precursor or a silver precursor, and the second cationic precursor is a zinc precursor, a copper precursor, a gallium precursor or an aluminum precursor.

Optionally, a material of the sacrificial sub-layer is selected from one or more of ZnN, ZnS, AlSb, ZnP, InP, AlS, PbS, HgS, AgS, ZnInS, ZnAlS, ZnSeS, CdSeS, CuInS, CuGaS, CuAlS, AgInS, AgAlS, AgGaS, ZnInP, ZnGaP, CdZnS, CdPbS, CdHgS, PbHgS, CdZnPbS, CdZnHgS, CdInZnS, CdAlZnS, CdSeZnS, AgInZnS, CuInZnS, AgGaZnS, CuGaZnS, CuZnSnS, CuAlZnS, CuCdZnS, MnS, ZnMnS, ZnPbS, WS, ZnWS, CoS, ZnCoS, NiS, ZnNiS, InS, SnS, and ZnSnS.

Optionally, a total thickness of the first sacrificial sub-layer to the nth sacrificial sub-layer is 5-15 nm.

The disclosure further provides a composition, including any of the above nanocrystalline or the nanocrystalline prepared by any of the above preparation method.

The disclosure further provides an optical film. The optical film includes a stacked first base material layer, light emitting layer and second base material layer. The light emitting layer includes the composition.

Optionally, the optical film does not include a water-oxygen barrier film. A Water Vapor Transmission Rate (VWTR) of the water-oxygen barrier film does not exceed 1 g/m²·24 h, and an Oxygen Transmission Rate (OTR) does not exceed 1 cm³/m²·24 h·0.1 Mpa.

Optionally, T₉₀ of the optical film under a blue light accelerated aging condition is greater than 1000 hours. The blue light accelerated aging condition includes an ambient temperature being 70° C., the intensity of the blue light is 150 mW/cm², and the wavelength of the blue light is 430-480 nm.

The disclosure further provides a light emitting device, including any of the above nanocrystalline or the nanocrystalline prepared by any of the above preparation method.

Through the adoption of the technical solutions of the disclosure, the nanocrystalline is resistant to etching. During use (in the presence of a photoexcitation condition), before the sacrificial shell layer material is completely consumed (sacrificed), changes in optical parameters of the nanocrystalline are also within a small range, so that the performance of the nanocrystalline is more stable during use, and the performance of a corresponding product is also more stable. In the preparation method, by controlling the changes of the optical parameters of the intermediate nanocrystallines during the coating and growing of the plurality of sacrificial sub-layers as small as possible, the stability of a final nanocrystalline product is improved. During the use of the nanocrystalline, as etching phenomenon occurs, the sacrificial shell layer coated outside the initial nanocrystalline is gradually consumed as an etching sacrificial agent, but the absorbance, the fluorescence emission peak wavelength, the FWHM and the QY of the nanocrystalline remain stable, so that problems that the nanocrystalline in the prior art is easy to oxidize and be etched under strong blue light, resulting in changes in spectrum and reduction or even quenching of the QY can be resolved. Therefore, the nanocrystalline has desirable stability in the application of non-barrier film products, and the cost of an optical product (for example, a QD film) or the light emitting device can be reduced.

### BRIEF DESCRIPTION OF THE DRAWINGS

FIG. 1 to FIG. 3 successively show transmission electron microscope photographs of a nanocrystalline according to Examples 1, 4, and 7 of the disclosure.

FIG. 4 to FIG. 7 successively show comparison line charts of changes in a fluorescence emission peak wavelength, a full width at half maximum, a QY, and absorbance of a QD film prepared in Example 10 and Comparative example 2 of the disclosure during blue light aging.

FIG. 8 to FIG. 11 successively show comparison line charts of changes in a fluorescence emission peak wavelength, a full width at half maximum, a QY, and absorbance (an excitation light wavelength is 450 nm) of a nanocrystalline of the disclosure during chemical etching, and each line chart includes corresponding curves of the nanocrystalline of Comparative example 1 and Examples 1 to 7.

FIG. 12 shows a comparison line chart of changes in a QY of the QD film prepared in Example 10 and Comparative example 2 of the disclosure under a high temperature and high humidity (650° C., 95%) storage aging condition.

FIG. 13 shows a comparison line chart of changes in the QY of the QD film prepared in Example 10 and Comparative example 2 of the disclosure under a high temperature storage aging condition (85° C.).

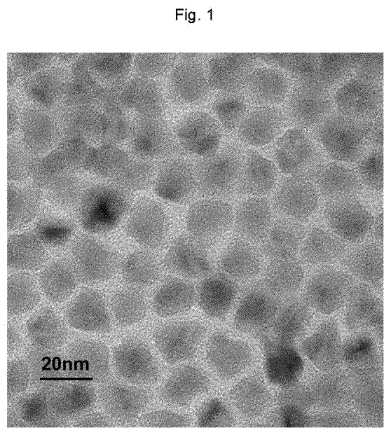

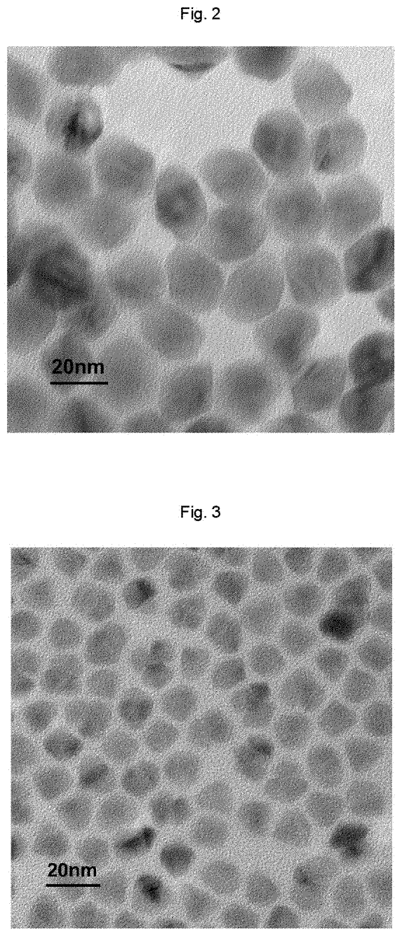

### DETAILED DESCRIPTION OF THE EXAMPLES

It is to be noted that terms “first”, “second” and the like in the description and claims of the disclosure are used for distinguishing similar objects rather than describing a specific sequence or a precedence order. It should be understood that the data used in such a way may be exchanged where appropriate, in order that the Examples of the disclosure described here can be implemented. In addition, terms “include” and “have” and any variations thereof are intended to cover non-exclusive inclusions. For example, it is not limited for processes, methods, systems, products or devices containing a series of steps or units to clearly list those steps or units, and other steps or units which are not clearly listed or are inherent to these processes, methods, products or devices may be included instead.

It should be noted that, the following detailed description is exemplary and intended to provide further description of the disclosure. Unless otherwise defined, all technical and scientific terms used herein have the same meaning as commonly understood by those of ordinary skill in the art to which the disclosure belongs. In the disclosure, a unit M for representing a solution concentration refers to mol/L, that is, 1M=1 mol/L. 3 Wt. % means that the mass fraction of a solution is 3%. An expression approach of [a, b] refers to a closed interval, that is, a numerical value greater than or equal to a and less than or equal to b. Quantum yield is abbreviated as QY. Full width at half maximum is abbreviated as FWHM.

An aspect of the disclosure provides a nanocrystalline, including an initial nanocrystalline and a sacrificial shell layer coated outside of the initial nanocrystalline. The sacrificial shell layer includes n sacrificial sub-layers sequentially coated outward with the initial nanocrystalline as the center, and the n sacrificial sub-layers may be of the same material or different materials. If the nanocrystalline is etched, at least a portion of the sacrificial shell layer is gradually consumed during etching. Fluorescence emission peak wavelength, FWHM, QY, and absorbance under excitation of an excitation light with a certain wavelength are measured m times during the etching. A maximum fluorescence emission peak wavelength and a minimum fluorescence emission peak wavelength in measurement results of m times are respectively set to be MAX_{PL} and MIN_{PL}; a maximum FWHM and a minimum FWHM respectively are MAX_{FWHM} and MIN_{FWHM}; a maximum QY and a minimum QY respectively are MAX_{QY} and MIN_{QY}; and maximum absorbance and minimum absorbance respectively are MAX_{AB} and MIN_{AB}, where 0≤MAX_{PL}−MIN_{PL}≤10 nm, 0≤MAX_{FWHM}−MIN_{FWHM}≤10 nm, 80%≤MIN_{QY}/MAX_{QY}≤100%, and 80%≤MIN_{AB}/MAX_{AB}≤100%, and n and m are integers greater than or equal to 1.

It is to be noted that, both the initial nanocrystalline and the sacrificial shell layer are made of a semiconductor material. In the disclosure, “sacrifice” or “etching” refers to a photochemical reaction of the nanocrystalline with water and oxygen under a certain light excitation condition, resulting in the consumption of a nanocrystalline material, or a chemical reaction of the nanocrystalline with a chemical etchant in the presence of the chemical etchant, resulting in the consumption of the nanocrystalline material. The above sacrifice or etching process occurs during the use of the nanocrystalline or a performance test of the nanocrystalline. In addition, the initial nanocrystalline and the sacrificial shell layer may have no obvious observable interface. A contact between the initial nanocrystalline and the sacrificial shell layer may be partially fused (or alloyed).

A wavelength of an excitation light configured to test changes in the absorbance of the nanocrystalline in the process of proactive etching the nanocrystalline is 350-900 nm. The selection of the wavelength of the excitation light is related to an emission wavelength of the nanocrystalline, and the wavelength of the excitation light is shorter than the emission wavelength of the nanocrystalline. For example, when the nanocrystalline is a nanocrystalline at an infrared-emitting band, the excitation light ranging from 460 to 900 nm may be selected. When the nanocrystalline is a purple-emitting nanocrystalline, the excitation light ranging from 300 to 430 nm may be selected. When the nanocrystalline is a nanocrystalline at a blue-emitting band, the excitation light ranging from 430 to 460 nm may be selected.

During the performance test, etching time required for the optical parameters of different nanocrystallines to produce a same changing value is different, and the length of the etching time is mainly related to a material and thickness of the sacrificial shell layer. The nanocrystalline of the present disclosure is resistant to etching, during use (in the presence of a photoexcitation condition), before the sacrificial shell layer material is completely consumed (sacrificed), changes in the optical parameters are within a small range, so that the performance of the nanocrystalline is more stable during use, and the performance of a corresponding product is also more stable.

In a preferred Example, the nanocrystalline is resistant to etching at an excitation wavelength ranging from 430 to 480 nm. In some Examples, n=1 and m=1. In this case, a measurement result during etching is compared with the fluorescence emission peak wavelength, FWHM, QY, and absorbance under excitation of an excitation light with a certain wavelength of the nanocrystalline before etching, as long as the following are met: 0≤larger value_{PL}-smaller value PL≤10 nm, 0≤larger value_{FWHM}−smaller value_{FWHM}≤10 nm, 80%≤smaller value_{QY}/larger valueQY≤00%, and 80%≤smaller value_{AB}/larger value_{AB}≤100%.

In some Examples, n and m are integers greater than or equal to 2.

In some Examples, n is an integer greater than or equal to 1 and m is an integer greater than or equal to 2.

In some Examples, 0≤MAX_{PL}−MIN_{PL}≤5 nm, and 0≤MAX_{FWHM}−MIN_{FWHM}≤5 nm.

In some Examples, 0≤MAX_{PL}−MIN_{PL}≤4 nm, or 0≤MAX_{PL}−MIN_{PL}3 nm, or 0≤MAX_{PL}−MIN_{PL}≤2 nm, or 0≤MAX_{PL}−MIN_{PL}≤1 nm.

In some Examples, 0≤MAX_{FWHM}−MIN_{FWHM}≤4 nm, or 0≤MAX_{FWHM}−MIN_{FWHM}≤3 nm, or 0≤MAX_{FWHM}−MIN_{FWHM}≤2 nm, or 0≤MAX_{FWHM}−MIN_{FWHM}≤1 nm, or 0≤MAX_{FWHM}−MIN_{FWHM}≤0.5 nm.

In some Examples, 85%≤MIN_{QY}/MAX_{QY}≤100%, or 90%≤MIN_{QY}/MAX_{QY}≤100%, or 95%≤MIN_{QY}/MAX_{QY}≤100%, or 98%≤MIN_{QY}/MAX_{QY}≤100%.

In some Examples, 85%≤MIN_{AB}/MAX_{AB}≤100%, or 90%≤MIN_{AB}/MAX_{AB}≤100%, or 95%≤MIN_{AB}/MAX_{AB}≤100%, or 98%≤MIN_{AB}/MAX_{AB}≤100%.

In some Examples, m is the integer greater than or equal to 2. During the etching, a difference between the fluorescence emission peak wavelengths of two adjacent measurements is [−2 nm, 2 nm]; a difference between the full widths at half maximum of two adjacent measurements is [−2 nm, 2 nm]; a percentage change in QY between two adjacent measurements is [−10%, 10%]; and a percentage change in absorbance between two adjacent measurements is [−10%, 10%]. The percentage change in the QY or the absorbance refers to a ratio of the difference between the two measurements to the first measurement result in the two measurements, and then multiplied by 100%. The two adjacent measurements refer to any two adjacent tests.

In some Examples, a material of the sacrificial shell layer may be selected from one or more of ZnN, ZnS, AlSb, ZnP, InP, AlS, PbS, HgS, AgS, ZnInS, ZnAlS, ZnSeS, CdSeS, CuInS, CuGaS, CuAlS, AgInS, AgAlS, AgGaS, ZnInP, ZnGaP, CdZnS, CdPbS, CdHgS, PbHgS, CdZnPbS, CdZnHgS, CdInZnS, CdAlZnS, CdSeZnS, AgInZnS, CuInZnS, AgGaZnS, CuGaZnS, CuZnSnS, CuAlZnS, CuCdZnS, MnS, ZnMnS, ZnPbS, WS, ZnWS, CoS, ZnCoS, NiS, ZnNiS, InS, SnS, and ZnSnS, which is not limited thereto. The chemical formulas of the material of the sacrificial shell layer listed above only represent elemental compositions. The ratio of each element may be adjusted according to actual requirements. For example, CdSeS may be expressed as CdSeₓS_{(1-X)}, where 0<X<1, and ZnSeS may be expressed as ZnSe_{Y}S_{(1-Y)}, where 0<Y<1.

In some Examples, n sacrificial sub-layers are made of a same material, which means that the material of each sacrificial sub-layer is composed of same chemical elements, but the mole ratio of the chemical elements in the material of each sacrificial sub-layer may be different, that is, the mole ratio may be adjusted. In a preferred Example, the material of the n sacrificial sub-layers is CdZnS, and the mass percentage of Cd in each CdZnS sacrificial sub-layer is 0-50%.

In some other Examples, the n sacrificial sub-layers are made of different materials, which mean that the materials of the n sacrificial sub-layers are completely different, or some of the n sacrificial sub-layers are made of the same material and the rest of the sacrificial sub-layers are made of different materials. The several sacrificial sub-layers made of the same material may be adjacent to each other or may be coated among the sacrificial sub-layers made of different materials at intervals. In some other Examples, the mole ratio of the chemical elements of the sacrificial sub-layers made of the same material is different, that is, the mole ratio may be adjusted.

In the disclosure, the initial nanocrystalline may be an alloy nanocrystalline or a core shell structure nanocrystalline, may be a binary nanocrystalline, a ternary nanocrystalline or a multicomponent nanocrystalline, or may be a QD, a nanosheet, a nanorod or a combination thereof. The alloy nanocrystalline may be a completely alloyed nanocrystalline, or may be a partially alloyed nanocrystalline. The binary nanocrystalline means that the main material of the nanocrystalline only contains two chemical elements. The ternary nanocrystalline means that the main material of the nanocrystalline only contains three chemical elements. The multicomponent nanocrystalline means that the main material of the nanocrystalline contains more than three chemical elements. The main material does not include chemical elements present in the nanocrystalline in a doped form. The chemical formulas of the materials of the initial nanocrystalline listed below only represent elemental compositions, and the ratio of the elements may be adjusted according to actual requirements. In some Examples, the initial nanocrystalline and/or the sacrificial shell layer includes doping elements.

In some Examples, the material of the initial nanocrystalline is CdSe, CdSeS, CdZnSe, CdZnSeS, CdS, CdZnS, InP, InZnP, InGaP, GaP, ZnTeSe, ZnSe, ZnTe, CuInS, CuInZnS, CuInZnSe, AgInZnSe, CuInSe, AgInSe, AgS, AgSe, AgSeS, PbS, PbSe, PbSeS, PbTe, HgS, HgSe, HgTe, CdHgTe, CgHgSe, CdHgS, CdTe, CdZnTe, CdTeSe, or CdTeS, which is not limited thereto.

In some Examples, the material of the initial nanocrystalline is CdSe/CdZnS, CdSe/ZnSe, CdSe/ZnSeS, CdSe/CdZnSeS, CdSe/ZnS, CdSe/CdSeS, CdSe/CdS, CdSe/CdZnSe, CdSeS/CdS, CdSeS/ZnS, CdSeS/CdZnS, CdSeS/ZnSeS, CdSeS/CdZnSe, CdSeS/ZnSe, CdSeS/ZnS, CdS/CdZnS, CdS/ZnS, CdS/CdSeS, CdZnS/CdZnSe, CdZnS/CdSe, CdZnS/CdSeS, CdZnSeS/CdZnS, CdZnSeS/CdZnSe, CdZnSeS/ZnS, CdZnSeS/ZnSeS, CdZnSe/ZnS, CdZnSe/CdZnS, CdZnSe/ZnSe, CdZnSe/ZnSeS, CdTe/CdS, CdTeSe/CdS, CdTeSe/CdSe/CdS, CdTeSe/CdSeS, CdZnTe/CdZnS, CdTe/CdS, InP/ZnS, InP/CdZnS, InP/ZnSe, InP/ZnSeS, InZnP/ZnS, InP/CuInZnS, InGaP/ZnS, ZnTeSe/ZnSe, ZnTeSe/ZnS, PbSe/PbS, PbSeS/PbS, PbTe/PbSe, PbTe/PbSeS, HgSe/HgS, HgTe/HgS, CdHgSe/CdHgS, CuInZnS/ZnS, CuInZnSe/CuInZnS, CuInSe/CuInS, AgSe/AgS, or AgInZnS/ZnS, which is not limited thereto.

The sacrificial sub-layer is a portion of the sacrificial shell layer, and a thickness of the sacrificial sub-layer is less than or equal to that of the sacrificial shell layer. In some Examples, the thickness of the sacrificial shell layer ranges from 5 to 15 nm. The sacrificial shell layer includes n sacrificial sub-layers sequentially coated outward with the initial nanocrystalline as the center, that is, the first sacrificial sub-layer, the second sacrificial sub-layer, . . . , the nth sacrificial sub-layer. A total thickness of the first sacrificial sub-layer to the nth sacrificial sub-layer ranges from 5 to 15 nm.

In some Examples, the number n of the sacrificial sub-layers is greater than or equal to 2 and less than or equal to 100. In some Examples, the sacrificial shell layer includes b monolayers, and b is greater than or equal to 2 and less than or equal to 20, preferably, 2≤b≤10. It is to be noted that, in the disclosure, each “sacrificial sub-layer” may include one or more monolayers, for example, 1 monolayer, 2 monolayers, 3 monolayers, 4 monolayers, and the like. The thicknesses of the monolayers of different sacrificial sub-layer materials are different. In some Examples, several sacrificial sub-layers as inner layers may partially cover the previous sacrificial sub-layers.

In some Examples, the number n of the sacrificial sub-layers equals to 1, and the thickness of the sacrificial sub-layer is not less than 5 nm.

Another aspect of the disclosure provides a method for preparing a nanocrystalline, including: S1, preparing an initial nanocrystalline; and S2, coating a sacrificial shell layer outside the initial nanocrystalline at one time or in steps, where the formed sacrificial shell layer includes n sacrificial sub-layers sequentially coated outward with the initial nanocrystalline as the center, respectively being the first sacrificial sub-layer, the second sacrificial sub-layer, . . . , the nth sacrificial sub-layer, and n is an integer greater than or equal to 1; an intermediate nanocrystalline with the first sacrificial sub-layer to the ith sacrificial sub-layer coated outside the initial nanocrystalline is denoted by an ith nanocrystalline, a fluorescence emission peak wavelength of the ith nanocrystalline is PLᵢ, FWHM of the ith nanocrystalline is FWHMᵢ, QY of the ith nanocrystalline is QYᵢ, and absorbance under excitation of an excitation light with a certain wavelength is ABSᵢ. When i takes all integers of [1, n], a maximum fluorescence emission peak wavelength and a minimum fluorescence emission peak wavelength in PLᵢ are respectively recorded as MAX_{PL} and MIN_{PL}; a maximum FWHM and a minimum FWHM in FWHMᵢ are respectively recorded as MAX_{FWHM} and MIN_{FWHM}; a maximum QY and a minimum QY in QYᵢ are respectively recorded as MAX_{QY} and MIN_{QY}; and maximum absorbance and minimum absorbance in ABSᵢ, are respectively recorded as MAX_{AB} and MIN_{AB}, and 0≤MAX_{PL}−MIN_{PL}≤10 nm, 0≤MAX_{FWHM}−MIN_{FWHM}≤10 nm, 80%≤MIN_{QY}/MAX_{QY}≤100%, and 80%≤MIN_{AB}/MAX_{AB}≤100%. “In FWHMᵢ”, “in QYᵢ” and “in ABSᵢ” represent in a set of corresponding parameters of each intermediate nanocrystalline.

It is to be noted that, each time the coating of the sacrificial sub-layer is performed, the intermediate nanocrystalline obtained in this step are purified after the coating reaction is completed, and then a partial purified intermediate nanocrystalline is taken to be redissolved in toluene. Then, a certain amount of toluene solution (the absorbance is adjusted to be 0.3) is taken for an integrating sphere test, to obtain the QYᵢ. Fluorescence spectrum measurement is performed on the intermediate nanocrystalline to obtain the fluorescence emission peak wavelength PLᵢ and the FWHMᵢ. A method for calculating the absorbance ABSᵢ, under excitation of an excitation light with a certain wavelength includes: taking 20 μL of a stock solution, and diluting the stock solution to 2 mL; measuring the absorbance by using an ultraviolet visible spectrophotometer and recording the absorbance as ODᵢ; and then measuring a total volume of the stock solution before dilution, recording the total volume as Vᵢ, where ABSᵢ=100×ODᵢ×Vᵢ.

In the disclosure, according to the principle that a nanocrystalline etching process and a nanocrystalline growth process are an opposite process, the nanocrystalline having a plurality of sacrificial sub-layers is designed. By controlling the changes of the optical parameters of the intermediate nanocrystallines during the coating and growing of the plurality of sacrificial sub-layers as small as possible, the stability of a final nanocrystalline product is improved. As etching phenomenon occurs, the sacrificial shell layer coated outside the initial nanocrystalline is gradually consumed as an etching sacrificial agent, however the absorbance, the fluorescence emission peak wavelength, the FWHM and the QY of the nanocrystalline remain stable, so that problems that the nanocrystalline in the prior art is easy to oxidize and etch under strong blue light, resulting in changes in spectrum and reduction or even quenching of the QY can be resolved. Therefore, the nanocrystalline has desirable stability in the application of non-barrier film products (for example, a QD film packaged with an ordinary PET film), and the cost of the optical film or the light emitting device can be reduced.

In some Examples, n is an integer greater than or equal to 2.

In some Examples, n=1, that is, the sacrificial shell layer is coated outside the initial nanocrystalline at one time in S2, and the thickness of the sacrificial shell layer is not less than 5 nm. In order to cause the optical parameters of the prepared nanocrystalline to conform to requirements of the disclosure, during the coating of the sacrificial shell layer at one time, the fluorescence emission peak wavelength, the FWHM, the QY, and the absorbance under excitation of the excitation light with the certain wavelength are measured by taking the reaction stock solution containing the intermediate nanocrystalline at least twice, and a measurement result needs to meet the following conditions: 0≤MAX_{PL}−MIN_{PL}≤10 nm, 0≤MAX_{FWHM}−MIN_{FWHM}≤10 nm, 80%≤MIN_{QY}/MAX_{QY}≤100%, and 80%≤MIN_{AB}/MAX_{AB}≤100%.

In some Examples, 0≤MAX_{PL}−MIN_{PL}≤5 nm, and 0≤MAX_{FWHM}−MIN_{FWHM}≤5 nm.

In some Examples, 0≤MAX_{PL}−MIN_{PL}≤4 nm, preferably, 0≤MAX_{PL}−MIN_{PL}≤3 nm, further preferably, 0≤MAX_{PL}−MIN_{PL}≤2 nm, more preferably, 0≤MAX_{PL}−MIN_{PL}≤1 nm.

In some Examples, 0≤MAX_{FWHM}−MIN_{FWHM}≤4 nm, preferably, 0≤MAX_{FWHM}−MIN_{FWHM}≤3 nm, further preferably, 0≤MAX_{FWHM}−MIN_{FWHM}≤2 nm, more preferably, 0≤MAX_{FWHM}−MIN_{FWHM}≤1 nm.

In some Examples, 85%≤MIN_{QY}/MAX_{QY}≤100%, preferably, 90%≤MIN_{QY}/MAX_{QY}≤100%, further preferably, 95%≤_{QY}/MAX_{QY}≤100%, more preferably, 98%≤MIN_{QY}/MAX_{QY}≤100%.

In some Examples, 85%≤MIN_{AB}/MAX_{AB}≤100%, preferably, 90%≤MIN_{AB}/MAX_{AB}≤100%, further preferably, 95%≤MIN_{AB}/MAX_{AB}≤100%, more preferably, 98%≤MIN_{AB}/MAX_{AB}≤100%.

In some Examples, a difference between the fluorescence emission peak wavelength of the (i−1)th nanocrystalline and the ith nanocrystalline is [−2 nm, 2 nm]; a difference between the FWHM is [−2 nm, 2 nm]; a percentage change in the QY is [−10%, 10%]; and a percentage change in the absorbance is [−10%, 10%].

In some Examples, the difference between the fluorescence emission peak wavelength of the (i−1)th nanocrystalline and the ith nanocrystalline is [−1.5 nm, 1.5 nm], [−1 nm, 1 nm], or [−0.5 nm, 0.5 nm].

In some Examples, the difference between the full width at half maximum of the (i−1)th nanocrystalline and the ith nanocrystalline is [−1.5 nm, 1.5 nm], [−≤1 nm, 1 nm], or [−0.5 nm, 0.5 nm].

In some Examples, the percentage change in the QY of the (i−1)th nanocrystalline and the ith nanocrystalline is [−5%, 5%], [−2%, 2%], or [−1%, 1%].

In some Examples, the percentage change in the absorbance of the (i−1)th nanocrystalline and the ith nanocrystalline is [−10%, 10%], [−5%, 5%], or [−1%, 1%].

In some Examples, the method for coating the ith sacrificial sub-layer in S2 includes: mixing the initial nanocrystalline or the (i−1)th nanocrystalline, one or more cationic precursors configured to form the ith sacrificial sub-layer, one or more anion precursors configured to form the ith sacrificial sub-layer, and a solvent for reaction, and obtaining the ith nanocrystalline coated with the ith sacrificial sub-layer after reaction. The optical parameters of the ith nanocrystalline are ensured to conform to the requirements by adjusting the types, ratios, addition amounts, rates of addition and concentrations of one or more cationic precursors and one or more anion precursors forming the ith sacrificial sub-layer. The adjustment process varies with the nanocrystallines of different materials.

In some Examples, the one or more cationic precursors configured to form the ith sacrificial sub-layer are selected from one or more of zinc precursor, aluminum precursor, indium precursor, lead precursor, mercury precursor, cadmium precursor, tin precursor, copper precursor, gallium precursor, tungsten precursor, manganese precursor, cobalt precursor, nickel precursor body, and silver precursor, which are not limited thereto. The one or more anion precursors configured to form the ith sacrificial sub-layer are selected from one or more of ammonium precursor, antimony precursor, sulfur precursor, phosphorus precursor, and selenium precursor, which are not limited thereto.

An example of the one or more cationic precursors configured to form the ith sacrificial sub-layer may include at least one of dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, zinc oleate, zinc stearate, aluminum oleate, aluminum monostearate, aluminum chloride, aluminum octoate, aluminum isopropoxide, trimethyl indium, indium acetate, indium hydroxide, indium chloride, indium oxide, indium nitrate, indium sulfate, lead acetate, lead bromide, lead chloride, lead fluoride, lead oxide, lead perchlorate, lead nitrate, lead sulfate, lead carbonate, mercury acetate, mercury iodide, mercury bromide, mercury chloride, mercury fluoride, mercury cyanide, mercury nitrate, mercury oxide, mercury perchlorate, mercury sulfate, dimethyl cadmium, diethyl cadmium, cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, tin acetate, tin bis(acetylacetonate), tin bromide, tin chloride, tin fluoride, tin oxide, tin sulfate, stannous isooctanoate, stannous oxalate, germanium tetrachloride, copper acetate, cuprous acetate, copper chloride, copper fluoride, copper iodide, trimethylgallium, triethylgallium, gallium acetylacetonate, gallium trichloride, gallium fluoride, gallium oxide, gallium nitrate, gallium sulfate, tungsten chloride, tungsten fluoride, tungsten bromide, tungsten iodide, tungsten oxide, manganese acetate, manganese stearate, manganese acetylacetonate, cobalt acetate, cobalt oxalate, nickel acetate, nickel bromide, nickel iodide, nickel acetylacetonate, nickel oxalate, silver nitrate, or silver acetate, which is not limited thereto.

An example of the one or more anion precursors configured to form the ith sacrificial sub-layer may include at least one of a combination of ammonia and dimethyl zinc, antimony tris(bis(trimethylsilyl)amide), Sulfur-Trioctylphosphine (S-TOP), Sulfur-Tributyl Phosphine (S-TBP), Sulfur-Triphenylphosphine (S-TPP), Sulfur-Trioctylamine (S-TOA), Sulfur-Octadecene (S-ODE), Sulfur-Diphenylphosphine (S-DPP), sulfur-oleylamine, sulfur-dodecylamine, dodecanethiol (DDT), octanethiol, alkyl phosphine, tris(trialkylmethylsilylphosphine), tris(dialkylamino)phosphine, Selenium-Trioctylphosphine (Se-TOP), Selenium-Tributyl Phosphine (Se-TBP), Selenium-Triphenylphosphine (Se-TPP), Selenium-Octadecene (Se-ODE), Selenium-Diphenylphosphine (Se-DPP), or Selenium-dodecylamine, which is not limited thereto.

In some Examples, the method for coating the ith sacrificial sub-layer in S2 includes: mixing the initial nanocrystalline or the (i−1)th nanocrystalline, one or more cationic precursors configured to form the ith sacrificial sub-layer, one or more anion precursors configured to form the ith sacrificial sub-layer, and a solvent for reaction for a certain period of time, then adding a doping agent containing a doping element to continue the reaction, and obtaining the ith nanocrystalline coated with the ith sacrificial sub-layer after the reaction. In some Examples, the doping element is at least one of In, Al, Ga, Cd, Pb, Hg, Mn, Ni, Co, Cr, W, Ag, or Cu. The optical parameters may conform to the requirements by adding the doping agent to adjust the optical parameters of the ith nanocrystalline.

In some Examples, the method for coating the ith sacrificial sub-layer in S2 includes: mixing the initial nanocrystalline or the (i−1)th nanocrystalline, one or more cationic precursors configured to form the ith sacrificial sub-layer, one or more anion precursors configured to form the ith sacrificial sub-layer, and a solvent in a container for reaction; when a fluorescence emission peak wavelength of a product in the container is blue-shifted in two adjacent monitoring, adding a first cationic precursor to the container at least once; and when the fluorescence emission peak wavelength of the product in the container is red-shifted in two adjacent monitoring, adding a second cationic precursor to the container at least once, and obtaining the ith nanocrystalline coated with the ith sacrificial sub-layer after reaction. On the premise of ensuring that the optical parameters of the ith nanocrystalline conform to the requirements, the types, addition amounts, rate of addition, concentrations and ratios of one or more cationic precursors and one or more anion precursors configured to form the ith sacrificial sub-layer may vary with the material and thickness of the shell layer. The addition number of the first cationic precursor or the second cationic precursor is mainly determined by the degree to which the fluorescence emission peak wavelength is red-shifted or blue-shifted, and the amount that the first cationic precursor or the second cationic precursor is added each time. During specific operation, it is only required that the four optical parameters of the ith nanocrystalline are within the required range.

The solvent may be, but is not limited to, C6 to C22 alkyl primary amine such as hexadecylamine, C6 to C22 alkyl secondary amine such as dioctylamine, C6 to C40 alkyl tertiary amine such as trioctylamine, nitrogen-containing heterocyclic compound such as pyridine, C6 to C40 olefin such as octadecene, C6 to C40 aliphatic hydrocarbon such as hexadecane, octadecane or squalane, aromatic hydrocarbons substituted by C6-C30 alkyl such as phenyldodecane, phenyltetradecane or phenylhexadecane, phosphine substituted by C6-C22 alkyl such as trioctylphosphine, phosphine oxide substituted by C6-C22 alkyl such as trioctylphosphine oxide, C12 to C22 aromatic ether such as phenyl ether or benzyl ether, or a combination thereof.

In order to further ensure that the optical parameters of the ith nanocrystalline conform to the requirements and improve the practicability of the preparation method, the above “blue-shifted” refers that the first cationic precursor starts to be added when, through real-time monitoring, the fluorescence emission peak wavelength of a product in the container is blue-shifted over about 2 nm in the two adjacent monitoring, and likewise, “red-shifted” refers that the second cationic precursor starts to be added in the container when the fluorescence emission peak wavelength is red-shifted over about 2 nm. However, it is to be noted that, the blue-shifting or red-shifting cannot exceed 10 nm at most, and preferably, does not exceed 5 nm. In addition, the preparation method is not further limited when the above blue-shifting or red-shifting exceeds 2 nm. That is to say, those skilled in the art realize the same technical effects of the disclosure by using specific implementations of controlling the blue-shifting or red-shifting to exceed about 0.1 nm, 1 nm, or 3 nm, which are all within the protection scope of the technical solutions of the disclosure.

In the above Example, the first cation of the first cationic precursor can cause the fluorescence emission peak wavelength of the nanocrystalline to red-shift. The second cation of the second cationic precursor can cause the fluorescence emission peak wavelength of the nanocrystalline to blue-shift. Therefore, the optical parameters of the ith nanocrystalline can be accurately controlled. In some Examples, the first cationic precursor is cadmium precursor, indium precursor or silver precursor, which is not limited thereto. The second cationic precursor is zinc precursor, copper precursor, gallium precursor or aluminum precursor, which is not limited thereto.

An example of the first cationic precursor may include at least one of dimethyl cadmium, diethyl cadmium, cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, trimethyl indium, indium acetate, indium hydroxide, indium chloride, indium oxide, indium nitrate, indium sulfate, silver diethyldithiocarbamate, silver nitrate, silver acetate, or silver oleate, which is not limited thereto.

An example of the second cationic precursor may include at least one of dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, zinc oleate, zinc stearate, copper acetate, cuprous acetate, copper chloride, copper fluoride, copper iodide, trimethylgallium, triethylgallium, gallium acetylacetonate, gallium trichloride, gallium fluoride, gallium oxide, gallium nitrate, gallium sulfate, aluminum oleate, aluminum monostearate, aluminum chloride, aluminum octoate, or aluminum isopropoxide, which is not limited thereto.

In the preparation method, a raw material for synthesis also includes a raw material for forming nanocrystalline ligand. Those skilled in the art may make selections as required.

In the disclosure, the nanocrystalline may be prepared by adopting any combination of the three methods for coating the ith sacrificial sub-layer. Those skilled in the art may also use other conventional synthesis methods to coat any sacrificial sub-layer.

In some Examples, a material of the sacrificial sub-layer may be selected from one or more of ZnN, ZnS, AlSb, ZnP, InP, AIS, PbS, HgS, AgS, ZnInS, ZnAlS, ZnSeS, CdSeS, CuInS, CuGaS, CuAlS, AgInS, AgAlS, AgGaS, ZnInP, ZnGaP, CdZnS, CdPbS, CdHgS, PbHgS, CdZnPbS, CdZnHgS, CdInZnS, CdAlZnS, CdSeZnS, AgInZnS, CuInZnS, AgGaZnS, CuGaZnS, CuZnSnS, CuAlZnS, CuCdZnS, MnS, ZnMnS, ZnPbS, WS, ZnWS, CoS, ZnCoS, NiS, ZnNiS, InS, SnS, and ZnSnS, which is not limited thereto. The chemical formulas of the material of the sacrificial sub-layer listed above only represent elemental combinations. The ratio of each element may be adjusted according to actual requirements. For example, CdSeS may be expressed as CdSe_{X}S_{(1-X)}, where 0<X<1, and ZnSeS may be expressed as ZnSe_{Y}S_{(1-Y)}, where 0<Y<1.

In some Examples, a total thickness of the first sacrificial sub-layer to the nth sacrificial sub-layer ranges from 5 to 15 nm.

In some Examples, the number n of the sacrificial sub-layers is greater than or equal to 2 and less than or equal to 20, preferably, 2≤n≤10.

In the disclosure, the initial nanocrystalline may be an alloy nanocrystalline or a core shell structure nanocrystalline, may be a binary nanocrystalline, a ternary nanocrystalline or a multicomponent nanocrystalline, or may be a quantum dot, a nanosheet, a nanorod, or a combination thereof.

In some Examples, the material of the initial nanocrystalline is CdSe, CdSeS, CdZnSe, CdZnSeS, CdS, CdZnS, InP, InZnP, InGaP, GaP, ZnTeSe, ZnSe, ZnTe, CuInS, CuInZnS, CuInZnSe, AgInZnSe, CuInSe, AgInSe, AgS, AgSe, AgSeS, PbS, PbSe, PbSeS, PbTe, HgS, HgSe, HgTe, CdHgTe, CgHgSe, CdHgS, CdTe, CdZnTe, CdTeSe, or CdTeS, which is not limited thereto.

In some Examples, the material of the initial nanocrystalline is CdSe/CdZnS, CdSe/ZnSe, CdSe/ZnSeS, CdSe/CdZnSeS, CdSe/ZnS, CdSe/CdSeS, CdSe/CdS, CdSe/CdZnSe, CdSeS/CdS, CdSeS/ZnS, CdSeS/CdZnS, CdSeS/ZnSeS, CdSeS/CdZnSe, CdSeS/ZnSe, CdSeS/ZnS, CdS/CdZnS, CdS/ZnS, CdS/CdSeS, CdZnS/CdZnSe, CdZnS/CdSe, CdZnS/CdSeS, CdZnSeS/CdZnS, CdZnSeS/CdZnSe, CdZnSeS/ZnS, CdZnSeS/ZnSeS, CdZnSe/ZnS, CdZnSe/CdZnS, CdZnSe/ZnSe, CdZnSe/ZnSeS, CdTe/CdS, CdTeSe/CdS, CdTeSe/CdSe/CdS, CdTeSe/CdSeS, CdZnTe/CdZnS, CdTe/CdS, InP/ZnS, InP/CdZnS, InP/ZnSe, InP/ZnSeS, InZnP/ZnS, InP/CuInZnS, InGaP/ZnS, ZnTeSe/ZnSe, ZnTeSe/ZnS, PbSe/PbS, PbSeS/PbS, PbTe/PbSe, PbTe/PbSeS, HgSe/HgS, HgTe/HgS, CdHgSe/CdHgS, CuInZnS/ZnS, CuInZnSe/CuInZnS, CuInSe/CuInS, AgSe/AgS, or AgInZnS/ZnS, which is not limited thereto.

Another aspect of the disclosure provides a composition, including any of the above nanocrystalline or the nanocrystalline prepared by any of the above preparation method. The composition is applicable to an optical material, a color conversion material, an ink, a coating, a taggant, a light emitting material, and the like.

In some Examples, the composition includes form of glue, polymer colloid, or a solvent. The composition is solid, liquid, or semi-solid.

In certain Examples, the amount of the main material in the composition may range from about 80 to about 99.5 weight percentage. An example of the main material specifically used includes, but is not limited to, polymer, oligomer, monomer, resin, adhesive, glass, metal oxide, and other non-polymeric materials. Preferably, the main material includes a polymeric and non-polymeric material, which is at least partially transparent, and preferably fully transparent, to preselected wavelengths of light.

Another aspect of the disclosure provides an optical film. The optical film includes a stacked first base material layer, light emitting layer and second base material layer. The light emitting layer includes the composition. Since the nanocrystalline of the disclosure is resistant to etching, the light emitting stability and service life of the optical film containing the nanocrystalline are enhanced. In some Examples, a thickness of the optical film is not limited. When the optical film reaches a certain thickness or more, the optical film is also called an optical plate.

In some Examples, the Water Vapor Transmission Rates (WVTR) of the first base material layer and the second base material layer are greater than 1 g/m²·24 h, and Oxygen Transmission Rates (OTR) are greater than 1 cm³/m²·24 h·0.1 Mpa. Thicknesses of the first base material layer and the second base material layer range from 20 to 200 μm. Materials of the first base material layer and the second base material layer may be, but are not limited to, PMMA, PVC, PP, PVDC, PE, BOPP, PA, PVA, CPP, or the like. A test condition of the WVTR is that a film thickness is 25 μm, a temperature is 23° C., and relative humidity is 0% RH.

In some Examples, the thicknesses of the first base material layer and the second base material layer range from 90 to 120 μm.

In some Examples, the thicknesses of the first base material layer and the second base material layer range from 20 to 80 μm.

In some Examples, the optical film does not include a water-oxygen barrier film. A WVTR of the water-oxygen barrier film does not exceed 1 g/m²·24 h, and an OTR does not exceed 1 cm³/m²·24 h·0.1 Mpa.

In some Examples, T₉₀ of the optical film under a blue light accelerated aging condition is greater than 1000 hours. The blue light accelerated aging condition includes an ambient temperature being 70° C., blue light intensity being 150 mW/cm², and a blue light wavelength ranging from 430 to 480 nm. T₉₀ refers to the aging time required for the brightness of the optical film to decrease to 90% of the initial brightness.

In some other Examples, the optical film includes a barrier film. The barrier film may be a high barrier film (VWTR: 0-0.5 g/m²·24 h, 2·24 h, OTR: 0-2 cm³/m²·24 h·0.1 Mpa), a medium barrier film (WVTR: 0.5-5 g/m²·24 h, OTR: 2-10 cm³/m²·24 h·0.1 Mpa), or a low barrier film (WVTR: 5-20 g/m²·24 h, OTR: 10-100 cm³/m²·24 h·0.1 Mpa).

In some other Examples, the optical film further includes a diffusion layer or a brightening layer, having diffusion or brightening functions. In this case, the optical film may also call nanocrystalline diffusion film or nanocrystalline brightening film. In some Examples, the optical film is a QD diffusion plate. Scattering particles are disposed in at least one of the first base material layer, the light emitting layer, or the second base material layer. In some Examples, the QD diffusion plate is integrally formed by a three-layer raw material melting and co-extrusion process.

Another aspect of the disclosure provides a light emitting device, including any of the above nanocrystalline or the nanocrystalline prepared by any of the above preparation method. Since the nanocrystalline of the disclosure is resistant to etching, the light emitting stability and service life of the light emitting device containing the nanocrystalline are enhanced. The light emitting device may be, but is not limited to, a liquid crystal display device, an OLED display device, a QLED display device, an LED packaging device including a lens, an electroluminescent or photoluminescent lighting device, or the like.

In some Examples, the light emitting device includes a primary light source. The nanocrystalline is disposed at a light exit of the primary light source, which may be in direct contact with the primary light source or in indirect contact with the primary light source. Then, wavelength conversion is performed on the light of the primary light source.

In some Examples, the light emitting device is a QD electroluminescent diode. A light emitting layer of the QD electroluminescent diode includes any of the above nanocrystalline.

Since the nanocrystalline of the disclosure is well resistant to photoetching and chemical etching, the nanocrystalline is applicable to biological detection, biological reagents, catalysis, and the like.

The beneficial effects of the disclosure will be further described below with reference to the Examples and comparative examples.

### EXAMPLE 1

Preparation of a Core-Shell Nanocrystalline CdSe/CdZnSeS/ZnInS/CdInZnS/ZnS:
1) 0.4 mmol of cadmium tetradecanoate, 0.1 mmol of selenium powder and 5 g of octadecene (ODE) were heated to 240° C. under nitrogen atmosphere for reaction for 20 min, then purification was performed to obtain CdSe cores with an average diameter being 4 nm, and the cores were dissolved in the ODE for later use.
2) 0.2 mmol of cadmium dodecanoate, 4 mmol of zinc acetate, 8 mmol of oleic acid and 10 g of ODE were heated to 300° C. under the nitrogen atmosphere. 0.05 mmol of the CdSe cores (which is calculated according to the molar quantity of Cd) in step 1 were injected. Then 1 mL of Se-TOP (2M) and 0.2 mL of S-TOP (2M) were injected. A reaction was performed for 20 min at 300° C. to obtain a CdSe/CdZnSeS nanocrystalline, the nanocrystalline was purified and dissolved in the ODE for later use, and the following: PL=610 nm, FWHM=20 nm, QY=78%, and absorbance ABS₄₅₀=300 are obtained through tests.
3) 0.05 mmol of indium tetradecanoate, 4 mmol of zinc acetate, 10 mmol of oleic acid and 10 g of ODE were heated to 300° C. under the nitrogen atmosphere. A purified CdSe/CdZnSeS nanocrystalline solution in step 2 was injected. Then 1.0 mL of S-TOP (2M) was injected. A reaction was performed for 10 min at 300° C. to obtain a CdSe/CdZnSeS/ZnInS nanocrystalline, the nanocrystalline was purified and dissolved in the ODE for later use, and the following: PL=611 nm, FWHM=23 nm, QY=76%, and absorbance ABS₄₅₀=310 were obtained through tests.
4) 0.02 mmol of indium tetradecanoate, 0.1 mmol of cadmium acetate, 4 mmol of zinc acetate, 8 mmol of oleic acid and 10 g of ODE were heated to 300° C. under the nitrogen atmosphere. A purified CdSe/CdZnSeS/ZnInS nanocrystalline solution in step 3 was injected. Then 1.0 mL of S-TOP (2M) was injected. A reaction was performed for 10 min at 300° C. to obtain a CdSe/CdZnSeS/ZnInS/CdInZnS nanocrystalline, the nanocrystalline was purified and dissolved in the ODE for later use, and the following: PL=609 nm, FWHM=21 nm, QY=79%, and absorbance ABS₄₅₀=315 were obtained through tests.
5) 4 mmol of zinc acetate, 8 mmol of oleic acid and 10 g of ODE are heated to 280° C. under the nitrogen atmosphere. A purified CdSe/CdZnSeS/ZnInS/CdInZnS nanocrystalline solution in step 4 was injected. Then 1 mol of octanethiol was added dropwise at 0.5 mol/h, and a temperature was heated to 300° C. after addition. Then, cooling was performed immediately, and purification was performed, to obtain a CdSe/CdZnSeS/ZnInS/CdInZnS/ZnS nanocrystalline, and the following: PL=610 nm, FWHM=22 nm, QY=80%, and absorbance ABS₄₅₀=315 were obtained through tests. A Transmission Electron Microscope (TEM) was used to respectively measure average diameters of the initial nanocrystalline and the final nanocrystalline, then the average diameters were subtracted from each other, and a total thickness of CdZnSeS/ZnInS/CdInZnS/ZnS sacrificial shell layers was calculated as 10 nm.

The fluorescence emission peak wavelength (PL) and the FWHM of the nanocrystalline were obtained by measuring the fluorescence emission spectrum of the nanocrystalline after each coating. The absorbance (ABSₓ) of the nanocrystalline under the excitation of an excitation light with a certain wavelength was measured by using an ultraviolet visible spectrophotometer, where the subscript x refers to the wavelength of the excitation light. The QY (QY) of the nanocrystalline was tested by using an integrating sphere. The PL, FWHM, QY, and ABSx obtained in the above step respectively form sets of parameters. Then maximum values and minimum values of the respective sets were solved, and MAX_{PL}−MIN_{PL}, MAX_{FWHM}−MIN_{FWHM}, MIN_{QY}/MAX_{QY}, and MIN_{AB}/MAX_{AB} were calculated. The following Examples and comparative examples were the same.

In Example 1, MAX_{PL}−MIN_{PL}=2 nm, MAX_{FWHM}−MIN_{FWHM}=2 nm, MIN_{QY}/MAX_{QY}=95.0%, and MIN_{AB}/MAX_{AB}=95.2%.

### EXAMPLE 2

Preparation of a Core-Shell Nanocrystalline CuInS/InZnS/CdZnS/AlZnS:
1) 0.2 mmol of indium tetradecanoate, 0.2 mmol of cuprous acetate, 0.5 mmol of oleic acid, 2 mmol of 1-dodecanethiol and 10 g of ODE were well mixed and heated to 170° C. under the nitrogen atmosphere. Then, 2 mL of an S-ODE (0.25M) solution was injected rapidly, a reaction was performed for 20 min to obtain a CuInS nanocrystalline, and the nanocrystalline was dissolved in the ODE for later use.
2) 2 mmol of zinc stearate, 0.1 mmol of indium tetradecanoate, and 2 mL of oleylamine and 5 mL of an S-ODE (0.25M) solution were added into the solution of step 1. Then, the solution was heated to 220° C. for reaction for 30 min. Purification was performed to obtain a CuInZnS/ZnInS nanocrystalline; the nanocrystalline was dissolved in the ODE for later use, and the following: PL=585 nm, FWHM=89 nm, QY=76%, and absorbance ABS₄₄₀=145 were obtained through tests.
3) 0.05 mmol of cadmium stearate, 4 mmol of zinc acetate, 8 mmol of oleic acid and 2 g of ODE were well mixed. A purified CuInZnS/ZnInS nanocrystalline solution in step 2 was injected under the nitrogen atmosphere, and then heated to 180° C. 6 mL of an S-ODE (0.25M) solution was injected, and heated to 230° C. for reaction for 20 min. Purification was performed to obtain a CuInZnS/ZnInS/CdZnS nanocrystalline, the nanocrystalline was dissolved in the ODE for later use, and the following: PL=584 nm, FWHM=86 nm, QY=75%, and absorbance ABS₄₄₀=150 were obtained through tests.
4) 0.05 mmol of aluminum acetate basic, 4 mmol of zinc acetate, 8 mmol of oleic acid and 1 mL of oleylamine were well mixed. A CuInZnS/ZnInS/CdZnS nanocrystalline solution in step 3 was injected under the nitrogen atmosphere, and then heated to 230° C. 0.5 mL of an S-TBP (4M) solution was injected for reaction for 60 min. Purification was performed to obtain a CuInZnS/ZnInS/CdZnS/AlZnS nanocrystalline; the nanocrystalline was dissolved in the ODE for later use, and the following: PL=585 nm, FWHM=85 nm, QY=79%, and absorbance ABS₄₄₀=154 were obtained through tests. Measurement was performed by the TEM, and a total thickness of InZnS/CdZnS/AlZnS sacrificial shell layers was calculated as 5 nm.

In Example 2, MAX_{PL}−MIN_{PL}=≤1 nm, MAX_{FWHM}−MIN_{FWHM}=4 nm, MIN_{QY}/MAX_{QY}=94.9%, and MIN_{AB}/MAX_{AB}=94.2%.

### EXAMPLE 3

Preparation of a Core-Shell Nanocrystalline AgInS/CuInZnS/AlZnS/InZnS/AlZnS:
1) 0.1 mmol of indium tetradecanoate, 0.1 mmol of silver nitrate, 0.15 mmol of oleic acid, and 0.2 mL of dodecyl mercaptan and 5 mL of ODE were well mixed, and heated to 90° C. under the nitrogen atmosphere. Then an S-OAM solution (dissolving 0.2 mmol of S into 1 mL of oleylamine) was rapidly injected, to obtain an AgInS initial nanocrystalline, and the nanocrystalline was dissolved in the ODE for later use.
2) 0.02 mol of cuprous acetate, 0.05 mol of indium tetradecanoate, 2 mmol of zinc stearate and 0.8 mL of oleylamine were added into the solution of step 1. Then, the solution was heated to 130° C., and 2 mL of an S-ODE (0.25M) solution was injected for reaction for 30 min at 140° C. Purification was performed to obtain an AgInS/CuInZnS nanocrystalline, the nanocrystalline was dissolved in the ODE for later use, and the following: PL=733 nm, FWHM=119 nm, QY=64%, and absorbance ABS₅₂₀=195 were obtained through tests.
3) 0.05 mmol of aluminum acetate basic, 2 mmol of zinc acetate, 4 mmol of oleic acid and 1 mL of oleylamine were well mixed. A purified AgInS/CuInZnS nanocrystalline solution in step 2 was injected under the nitrogen atmosphere, and then heated to 180° C. 4 mL of an S-ODE (0.25M) solution was injected for reaction for 30 min. Purification was performed to obtain an AgInS/CuInZnS/AlZnS nanocrystalline; the nanocrystalline was dissolved in the ODE for later use, and the following: PL=738 nm, FWHM=115 nm, QY=75%, and absorbance ABS₅₂₀=200 were obtained through tests.
4) 2 mmol of zinc stearate, 0.05 mmol of indium tetradecanoate, 2 mL of oleylamine and 5 mL of an S-ODE (0.25M) solution were added into the solution of step 3. Then, the solution was heated to 190° C. for reaction for 10 min. Purification was performed to obtain an AgInS/CuInZnS/AlZnS/ZnInS nanocrystalline; the nanocrystalline was dissolved in the ODE for later use, and the following: PL=735 nm, FWHM=117 nm, QY=77%, and absorbance ABS₅₂₀=205 were obtained through tests.
5) 0.05 mmol of aluminum acetate basic, 4 mmol of zinc acetate, 8 mmol of oleic acid and 1 mL of oleylamine were well mixed. A purified CuInZnS/ZnInS/CdZnS nanocrystalline solution in step 3 was injected under the nitrogen atmosphere, and then heated to 230° C. 0.5 mL of an S-TBP (4M) solution was injected for reaction for 5 min. Purification was performed to obtain an AgInS/CuInZnS/AlZnS/ZnInS/AlZnS nanocrystalline; the nanocrystalline was dissolved in the ODE for later use, and the following: PL=735 nm, FWHM=115 nm, QY=80%, and absorbance ABS₅₂₀=200 were obtained through tests. Measurement was performed by the TEM, and a total thickness of CuInZnS/AlZnS/InZnS/AlZnS sacrificial shell layers was calculated as 9 nm.

In Example 3, MAX_{PL}−MIN_{PL}=5 nm, MAX_{FWHM}−MIN_{FWHM}=4 nm, MIN_{QY}/MAX_{QY}=80.0%, and MIN_{AB}/MAX_{AB}=95.1%.

### EXAMPLE 4

Preparation of a Core-Shell Nanocrystalline CdSe/CdZnS/CuInZnS/ZnAlS/CdZnS:
1) 0.1 mmol of cadmium stearate, 0.1 mmol of selenium powder and 5 g of ODE were well mixed and heated to 240° C. under the nitrogen atmosphere for reaction for 10 min, then purification was performed to obtain CdSe cores, and the cores were dissolved in the ODE for later use.
2) 0.05 mmol of cadmium stearate, 4 mmol of zinc acetate and 8 mmol of oleic acid were well mixed. A purified CdSe core solution in step 1 was injected under the nitrogen atmosphere, and then heated to 280° C. 2 mmol of dodecyl mercaptan was injected, and heated to 300° C. for reaction for 30 min. Purification was performed to obtain a CdSe/CdZnS nanocrystalline, the nanocrystalline was dissolved in the ODE for later use, and the following: PL=522 nm, FWHM=24 nm, QY=75%, and absorbance ABS₄₅₀=125 were obtained through tests.
3) 0.02 mol of cuprous acetate, 0.05 mol of indium tetradecanoate, 2 mmol of zinc stearate and 0.8 mL of oleylamine were well mixed. A purified CdSe/CdZnS nanocrystalline solution in step 2 was injected under the nitrogen atmosphere, and then heated to 130° C. 2 mL of an S-ODE (0.25M) solution was injected for reaction for 30 min at 140° C. Purification was performed to obtain a CdSe/CdZnS/CuInZnS nanocrystalline, the nanocrystalline was dissolved in the ODE for later use, and the following: PL=520 nm, FWHM=25 nm, QY=74%, and absorbance ABS₄₅₀=130 were obtained through tests.
4) 0.05 mmol of aluminum acetate basic, 2 mmol of zinc acetate, 4 mmol of oleic acid and 1 mL of oleylamine were well mixed. A purified CdSe/CdZnS/CuInZnS nanocrystalline solution in step 3 was injected under the nitrogen atmosphere, and then heated to 280° C. 2 mL of an S-TBP (2M) solution was injected for reaction for 30 min. Purification was performed to obtain a CdSe/CdZnS/CuInZnS/AlZnS nanocrystalline; the nanocrystalline was dissolved in the ODE for later use, and the following: PL=521 nm, FWHM=24 nm, QY=76%, and absorbance ABS₄₅₀=128 were obtained through tests.
5) 0.2 mmol of cadmium stearate, 4 mmol of zinc acetate and 8 mmol of oleic acid were well mixed. A purified CdSe/CdZnS/CuInZnS/AlZnS nanocrystalline solution in step 4 was injected under the nitrogen atmosphere, and then rapidly heated to 300° C. 2 mmol of dodecyl mercaptan was injected for reaction for 30 min. Purification was performed to obtain a CdSe/CdZnS/CuInZnS/AlZnS/CdZnS nanocrystalline; the nanocrystalline was dissolved in the ODE for later use, and the following: PL=522 nm, FWHM=22 nm, QY=78%, and absorbance ABS₄₅₀=130 were obtained through tests. Measurement was performed by using the TEM, and a total thickness of CdZnS/CuInZnS/ZnAlS/CdZnS sacrificial shell layers was calculated as 15 nm.

In Example 4, MAX_{PL}−MIN_{PL}=5 nm, MAX_{FWHM}−MIN_{FWHM}=2 nm, MIN_{QY}/MAX_{QY}=94.8%, and MIN_{AB}/MAX_{AB}=96.2%.

### EXAMPLE 5

Preparation of a Core-Shell Nanocrystalline CdS/CdZnS/ZnInS/ZnAlS/CdAlZnS:
1) 0.1 mmol of cadmium stearate, 0.1 mmol of sulfur powder and 10 g of ODE were well mixed, and rapidly heated to 240° C. under the nitrogen atmosphere for reaction for 5 min, then purification was performed to obtain a CdS core nanocrystalline, and the nanocrystalline was dissolved in the ODE for later use.
2) 0.2 mmol of cadmium stearate, 3 mmol of zinc stearate, 2 mmol of oleic acid and 10 g of ODE were well mixed, and heated to 310° C. A purified CdS core nanocrystalline solution in step 1 and 2 mL of an S-TBP (1M) solution were successively injected, for reaction for 60 min at 310° C. Purification was performed to obtain a CdS/CdZnS nanocrystalline, the nanocrystalline was dissolved in the ODE for later use, and the following: PL=445 nm, FWHM=22 nm, QY=89%, and absorbance ABS₃₉₅=450 were obtained through tests.
3) 2 mmol of zinc stearate, 0.05 mmol of indium tetradecanoate and 2 mL of oleylamine were well mixed. A purified CdS/CdZnS nanocrystalline solution in step 2 was injected under the nitrogen atmosphere, and then heated to 180° C. 5 mL of an S-ODE (0.25M) solution was injected, and then heated to 240° C. for reaction for 10 min. Purification was performed to obtain a CdS/CdZnS/ZnInS nanocrystalline; the nanocrystalline was dissolved in the ODE for later use, and the following: PL=442 nm, FWHM=20 nm, QY=87%, and absorbance ABS₃₉₅=445 were obtained through tests.
4) 0.2 mmol of aluminum acetate basic, 2 mmol of zinc oleate and 4 mmol of oleic acid were well mixed. A purified CdS/CdZnS/ZnInS nanocrystalline solution in step 3 was injected under the nitrogen atmosphere, and then heated to 300° C. 1 mL of an S-TBP (2M) solution was injected for reaction for 60 min, to obtain a CdS/CdZnS/ZnInS/ZnAlS nanocrystalline, the nanocrystalline was dissolved in the ODE for later use, and the following: PL=443 nm, FWHM=22 nm, QY=88%, and absorbance ABS₃₉₅=440 were obtained through tests.
5) 0.2 mmol of cadmium stearate, 0.2 mol of aluminum acetate basic, 4 mmol of zinc stearate, 10 mmol of oleic acid and 10 g of ODE were replenished in the solution of step 4, and heated to 310° C. 1 mL of an S-TBP (2M) solution was injected, for reaction for 60 min at 310° C. Purification was performed to obtain a CdS/CdZnS/ZnInS/ZnAlS/CdAlZnS nanocrystalline, the nanocrystalline was dissolved in the ODE for later use, and the following: PL=445 nm, FWHM=20 nm, QY=92%, and absorbance ABS₃₉₅=460 were obtained through tests. Measurement was performed by using the TEM, and a total thickness of CdZnS/ZnInS/ZnAlS/CdAlZnS sacrificial shell layers was calculated as 7 nm.

In Example 5, MAX_{PL}−MIN_{PL}=3 nm, MAX_{FWHM}−MIN_{FWHM}=2 nm, MIN_{QY}/MAX_{QY}=94.5%, and MIN_{AB}/MAX_{AB}=96.7%.

### EXAMPLE 6

Preparation of a Core-Shell Nanocrystalline InZnP/ZnSeS/CdZnS/CuCdZnS/AlZnS:
1) 0.1 mmol of indium oleate, 0.25 mmol of zinc oleate and 10 g of ODE were well mixed, and heated to 120° C. under the nitrogen atmosphere. 0.1 mmol of (TMS)₃P was injected and rapidly heated to 300° C. for reaction for 10 min, to obtain an InZnP core nanocrystalline.
2) 3 mmol of zinc oleate, 0.5 mL of Se-TBP (2M) and 0.5 mL of S-TBP (2M) were added into the nanocrystalline stock solution in step 1 under the nitrogen atmosphere. Then, the solution was heated to 300° C. for reaction for 30 min. Purification was performed to obtain an InZnP/ZnSeS nanocrystalline; the nanocrystalline was dissolved in the ODE for later use, and the following: PL=530 nm, FWHM=30 nm, QY=93%, and absorbance ABS₄₅₀=240 were obtained through tests.
3) 4 mmol of zinc stearate, 2 mmol of oleic acid and 10 g of ODE were well mixed, and heated to 310° C. A purified InZnP/ZnSeS nanocrystalline solution in step 2 and 2 mL of an S-TBP (1M) solution were successively injected. A fluorescence emission peak wavelength was monitored in real time. When the wavelength starts to blue-shift, 0.01 mmol of cadmium oleate was replenished. When the wavelength starts to red-shift, 0.5 mmol of zinc oleate was replenished. A reaction was performed for 60 min at 310° C. Purification was performed to obtain an InZnP/ZnSeS/CdZnS nanocrystalline, the nanocrystalline was dissolved in the ODE for later use, and the following: PL=530 nm, FWHM=29 nm, QY=94%, and absorbance ABS₄₅₀=245 were obtained through tests.
4) 4 mmol of zinc stearate, 2 mmol of oleic acid and 10 g of ODE were well mixed, and heated to 310° C. A purified InZnP/ZnSeS/CdZnS nanocrystalline solution in step 3 and 2 mL of an S-TBP (1M) solution were successively injected. The fluorescence emission peak wavelength was monitored in real time. When the wavelength starts to blue-shift, 0.01 mmol of cadmium oleate was replenished. When the wavelength starts to red-shift, 0.001 mmol of copper oleate was replenished. A reaction was performed for 30 min at 310° C. Purification was performed to obtain an InZnP/ZnSeS/CdZnS/CuCdZnS nanocrystalline, the nanocrystalline was dissolved in the ODE for later use, and the following: PL=530 nm, FWHM=28 nm, QY=95%, and absorbance ABS₄₅₀=240 were obtained through tests.
5) 0.2 mmol of aluminum acetate basic, 2 mmol of zinc stearate, 6 mmol of oleic acid and 10 g of ODE were well mixed. A purified InZnP/ZnSeS/CdZnS/CuCdZnS nanocrystalline solution in step 4 was injected under the nitrogen atmosphere, and then heated to 300° C. 1 mL of an S-TBP (2M) solution was injected for reaction for 60 min. Purification was performed to obtain an InZnP/ZnSeS/CdZnS/CuCdZnS/AlZnS nanocrystalline; the nanocrystalline was dissolved in the ODE for later use, and the following: PL=530 nm, FWHM=28 nm, QY=94%, and absorbance ABS₄₅₀=245 were obtained through tests. Measurement was performed by the TEM, and a total thickness of InZnP/ZnSeS/CdZnS/CuCdZnS/AlZnS sacrificial shell layers was calculated as 6 nm.

In Example 6, MAX_{PL}−MIN_{PL}=0 nm, MAX_{FWHM}−MIN_{FWHM}=2 nm, MIN_{QY}/MAX_{QY}=97.9%, and MIN_{AB}/MAX_{AB}=98.0%.

### EXAMPLE 7

Preparation of a Core-Shell Nanocrystalline CdSeS/CdZnS/CdZnS/CdZnS/CdZnS:
1) 2 mmol of cadmium stearate, 0.8 mmol of selenium powder, 0.2 mmol of sulfur powder and 5 g of ODE were well mixed; and heated to 240° C. under the nitrogen atmosphere for reaction for 10 min, then purification was performed to obtain CdSeS cores, and the cores were dissolved in the ODE for later use.
2) 0.2 mmol of cadmium stearate, 4 mmol of zinc acetate and 8 mmol of oleic acid were well mixed. 0.1 mmol of a purified CdSeS core solution (which was calculated according to the molar quantity of Cd) in step 1 was injected under the nitrogen atmosphere, and then rapidly heated to 300° C. 2 mmol of dodecyl mercaptan was injected, and heated to 300° C. for reaction for 30 min. Purification was performed to obtain a CdSeS/CdZnS nanocrystalline, the nanocrystalline was dissolved in the ODE for later use, and the following: PL=525 nm, FWHM=30 nm, QY=78%, and absorbance ABS₄₅₀=155 were obtained through tests.
3) 0.25 mmol of cadmium stearate, 4 mmol of zinc oleate and 8 mL of ODE were well mixed. A purified CdSeS/CdZnS nanocrystalline solution in step 2 was injected under the nitrogen atmosphere, and then rapidly heated to 300° C. 2 mmol of dodecyl mercaptan was injected for reaction for 30 min. Purification was performed to obtain a CdSe/CdZnS/CdZnS nanocrystalline; the nanocrystalline was dissolved in the ODE for later use, and the following: PL=523 nm, FWHM=28 nm, QY=76%, and absorbance ABS₄₅₀=145 were obtained through tests.
4) 0.3 mmol of cadmium stearate, 4 mmol of zinc oleate and 8 mL of ODE were well mixed. A purified CdSeS/CdZnS/CdZnS nanocrystalline solution in step 3 was injected under the nitrogen atmosphere, and then rapidly heated to 300° C. 2 mmol of dodecyl mercaptan was injected for reaction for 30 min. Purification was performed to obtain a CdSe/CdZnS/CdZnS/CdZnS nanocrystalline; the nanocrystalline was dissolved in the ODE for later use, and the following: PL=524 nm, FWHM=27 nm, QY=75%, and absorbance ABS₄₅₀=140 were obtained through tests.
5) 0.6 mmol of cadmium stearate, 4 mmol of zinc oleate and 8 mL of ODE were well mixed. A purified CdSeS/CdZnS/CdZnS/CdZnS nanocrystalline solution in step 4 was injected under the nitrogen atmosphere, and then rapidly heated to 300° C. 1 mL of a 2 mmol/mL S-TOP solution was injected for reaction for 30 min. Purification was performed to obtain a CdSe/CdZnS/CdZnS/CdZnS/CdZnS nanocrystalline; the nanocrystalline was dissolved in the ODE for later use, and the following: PL=524 nm, FWHM=25 nm, QY=83%, and absorbance ABS₄₅₀=150 were obtained through tests. Measurement was performed by using the TEM, and a total thickness of CdZnS/CdZnS/CdZnS/CdZnS sacrificial shell layers was calculated as 10 nm.

In Example 7, MAX_{PL}−MIN_{PL}=2 nm, MAX_{FWHM}−MIN_{FWHM}=5 nm, MIN_{QY}/MAX_{QY}=90.4%, and MIN_{AB}/MAX_{AB}=90.3%.

### EXAMPLE 8

Preparation of a Core-Shell Nanocrystalline CdZnSeS/CdZnInS:
1) 0.2 mmol of cadmium stearate, 3 mmol of zinc oleate, and 2 g of oleic acid and 10 g of ODE were heated to 310° C. A mixed solution of 1.5 mL of 1 mmol/mL Se-TOP and 1.5 mL of 1 mmol/mL S-TOP was injected under the nitrogen atmosphere. A reaction was performed for 30 min at 300° C., and then cooled to room temperature, to obtain a CdZnSeS initial nanocrystalline.
2) 10 mmol of zinc acetate and 30 mmol of oleic acid were replenished in the above step. Nitrogen was introduced. A temperature was heated to 180° C. and maintained for 30 min. 4 mL of a 2 mmol/mL S-TBP solution was injected, and heated to 300° C. When the reaction was performed for 10 min, 1 mL of 0.2 mmol/mL cadmium oleate precursor was added. When the reaction was performed for 30 min, 1 mL of a 0.2 mmol/mL indium oleate precursor was added. When the reaction was performed for 60 min, 1 mL of a 0.2 mmol/mL indium oleate was added. When the reaction was performed for 90 min, the temperature stops to be heated and cooled to room temperature, and then purification was performed to obtain a CdZnSeS/CdZnInS nanocrystalline. The following: PL=524 nm, FWHM=25 nm, QY=83%, and absorbance ABS₄₅₀=300 were obtained through tests. Measurement was performed by the TEM, and a total thickness of CdZnSeS/CdZnInS sacrificial shell layers was calculated as 5 nm.

### EXAMPLE 9

Preparation of a Core-Shell Nanocrystalline CdSe/CdZnSeS/CdZnInS:
1) 0.1 mmol of cadmium stearate, 0.1 mmol of selenium powder and 5 g of ODE were well mixed and heated to 240° C. under the nitrogen atmosphere for reaction for 10 min, then purification was performed to obtain CdSe cores, and the cores were dissolved in the ODE for later use.
2) 0.05 mmol of cadmium stearate, 4 mmol of zinc oleate and 8 mmol of oleic acid were well mixed. A purified CdSe core solution in step 1 was injected under the nitrogen atmosphere, and then rapidly heated to 300° C. A mixed solution of 1.5 mL of 1 mmol/mL Se-TOP and 1.5 mL of 1 mmol/mL S-TOP was injected for reaction for 30 min. Purification was performed to obtain a CdSe/CdZnSeS initial nanocrystalline, the nanocrystalline was dissolved in the ODE for later use.
3) The ODE solution of the CdSe/CdZnSeS nanocrystalline in the above step, 12 mmol of zinc acetate and 30 mmol of oleic acid were heated to 180° C. under the nitrogen atmosphere and maintained for 30 min. 5 mL of a 2 mmol/mL S-TBP solution was injected, and heated to 300° C. When the reaction was performed for 10 min, 2 mL of 0.2 mmol/mL cadmium oleate precursor was added. When the reaction was performed for 30 min, 1 mL of a 0.2 mmol/mL indium oleate precursor was added. When the reaction was performed for 60 min, 1 mL of a 0.2 mmol/mL indium oleate was added. When the reaction was performed for 90 min, the temperature stops to be heated and cooled to room temperature, and then purification was performed to obtain a CdSe/CdZnSeS/CdZnInS nanocrystalline. The following: PL=550 nm, FWHM=20 nm, QY=80%, and absorbance ABS₄₅₀=320 were obtained through tests. Measurement was performed by using the TEM, and a total thickness of CdSe/CdZnSeS/CdZnInS sacrificial shell layers was calculated as 5 nm.

### COMPARATIVE EXAMPLE 1

Preparation of a CdSeZnS/ZnS Nanocrystalline:

0.16 mmol of cadmium oleate, 4 mmol of zinc oleate and 10 g of ODE were well mixed, and then heated to 310° C. under the nitrogen atmosphere. A mixed solution of 2 mmol of Se-TOP and 1 mmol of S-TBP was rapidly injected. A reaction was performed for 30 min at 300° C., and then cooled to room temperature, to obtain a CdSeZnS nanocrystalline. The following: PL=530 nm, FWHM=23 nm, QY=85%, and absorbance ABS₄₅₀=240 were obtained through tests.

8 mmol of zinc oleate and 6 mmol of dodecyl mercaptan were added into the solution of the above step. Then, the solution was heated to 310° C. for reaction for 60 min. Purification was performed to obtain a CdZnSeS/ZnS nanocrystalline, the nanocrystalline was dissolved in the ODE for later use, and the following: PL=520 nm, FWHM=25 nm, QY=90%, and absorbance ABS₄₅₀=220 were obtained through tests. Measurement was performed by using the TEM, and a total thickness of ZnS shell layers was calculated as 6 nm.

A method for purifying the nanocrystalline includes the following.

10 mL of a stock solution was put into a 50 mL centrifuge tube, about 30 mL of acetone was added, and then high speed centrifugation was performed at 4000 rpm for 5 min. The solution was taken out, and supernatant was discarded. The precipitate was dissolved into a certain amount of a toluene, ODE or glue composition.

### EXAMPLE 10

A method for preparing a QD film includes the following.

A PET base layer with a thickness being 100 μm was prepared. The WVTR of the PET base layer was about 10 g/m²·24 h, and the OTR was about 20 cm³/m²·24 h·0.1 MPa. Nanocrystalline glue was disposed on the PET base layer, and the PET base layer was then disposed on the nanocrystalline glue. Then, the nanocrystalline glue was cured to form a nanocrystalline glue layer with a thickness being 100 μm, to obtain the QD film. The nanocrystalline glue was acrylic polymer based UV glue. The nanocrystalline in the nanocrystalline glue adopts the nanocrystallines prepared in Examples 1, 2, 4, 6 and 7. The mass fraction of the nanocrystalline was 5%; the mass fraction of acrylic monomer was 20%; the mass fraction of acrylic polymer was 69.7%; and the mass fraction of other additives was 5.3%.

### COMPARATIVE EXAMPLE 2

A difference between this comparative example and Example 10 lies in that, the nanocrystalline in the nanocrystalline glue adopts the nanocrystalline prepared in Comparative example 1.

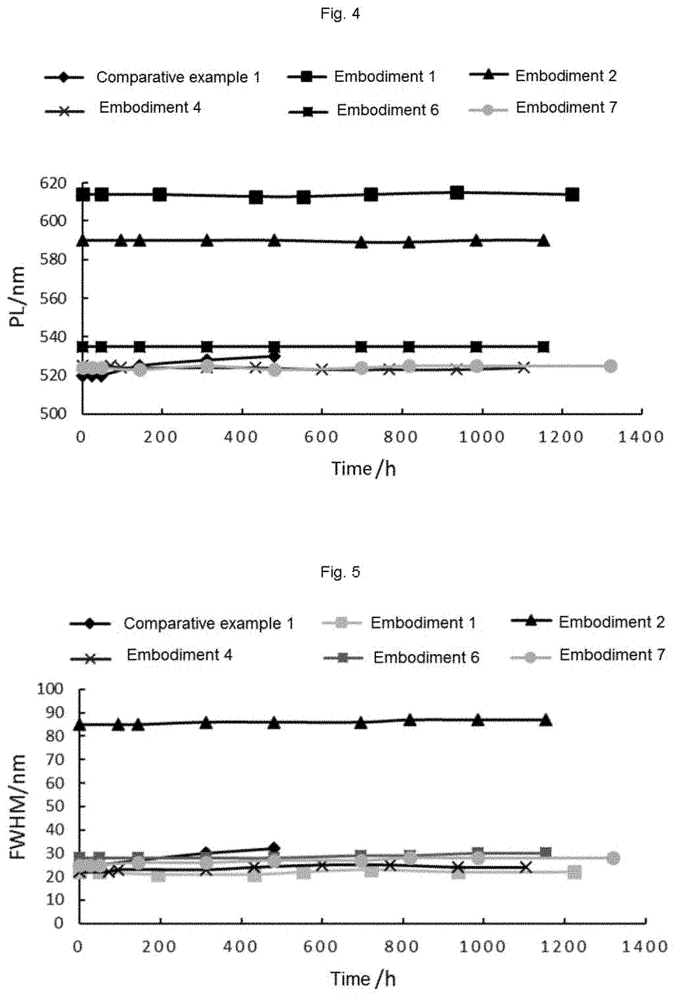

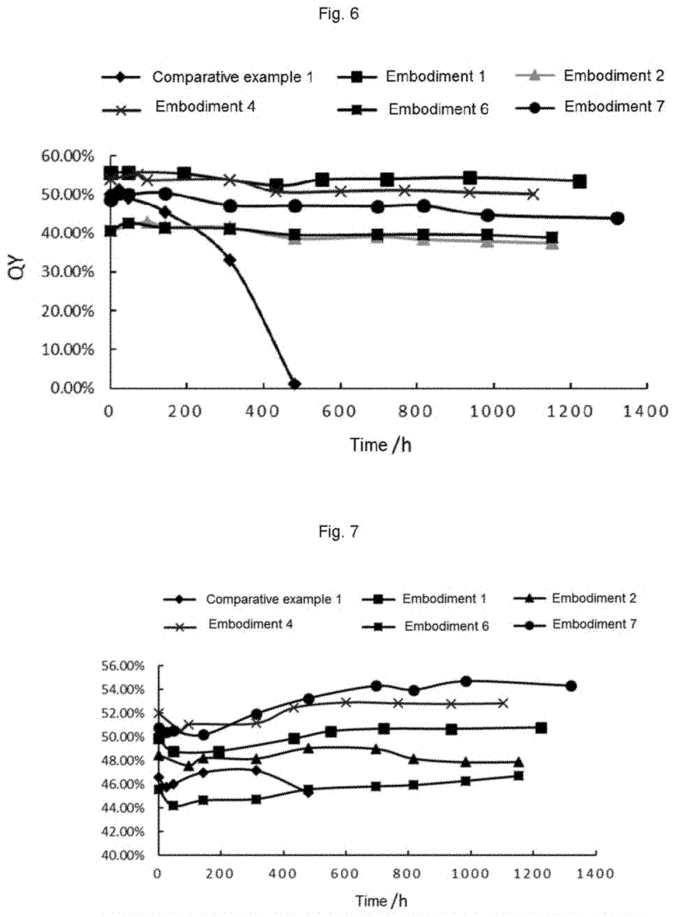

T₉₀ of the QD films prepared in Example 10 and Comparative example 2 was tested under an aging condition of an ambient temperature being 70° C., a blue light intensity being 150 mW/cm², and a blue light wavelength being 450 nm. During blue light aging, the fluorescence emission peak wavelength (PL) and FWHM of the QD film were measured for a plurality of times by using a fluorescence spectrum; the QY and blue light absorbance a of the QD film were measured by using the integrating sphere. Since the absorbance ABS₄₅₀ and the blue light absorbance a of the QD film have the following relationship: ABS₄₅₀=Ig[1/(1−a)], the measurement of the absorbance of the QD film using the integrating sphere was more convenient, the blue light absorbance a of the QD film at 450 nm was used to represent the absorbance. Then, measured data were respectively made into line charts for comparison, referring to FIG. 4, FIG. 5, FIG. 6 and FIG. 7.

FIG. 6 shows a comparison line chart of changes in the QY of the QD film prepared in Example 10 and Comparative example 2 during blue light aging. It may be seen from FIG. 6 that, the T₉₀ of the QD films prepared by the nanocrystallines in Examples 1, 2, 4, 6 and 7 was greater than 1000 hours (an initial QY of Example 1 was 55.65%, and the QY after aging for 1224 hours was 53.53%; an initial QY of Example 2 was 40.62%, and the QY after aging for 1152 hours was 37.49%; an initial QY of Example 4 was 53.92%, and the QY after aging for 1104 hours was 50.16%; an initial QY of Example 6 was 40.58%, and the QY after aging for 1152 hours was 38.87%; and an initial QY of Example 7 was 48.64%, and the QY after aging for 1320 hours was 43.92%). The T₉₀ of the QD film prepared by the nanocrystalline in Comparative example 1 was close to 144 hours (an initial QY of Comparative example 1 was 49.97%; and the QY after aging for 144 hours was 45.51%). Therefore, the stability and service life of the nanocrystalline of the disclosure were obviously better than those of the nanocrystalline of Comparative example 1 that does not have the sacrificial shell layers.

FIG. 4, FIG. 5 and FIG. 7 respectively show comparison line charts of changes in fluorescence emission peak wavelength, a full width at half maximum, QY, and blue light absorbance of QD film prepared in Example 10 and Comparative example 2 during blue light aging. MAX_{PL}−MIN_{PL}, MAX_{FWHM}−MIN_{FWHM}, MIN_{QY}/MAX_{QY}, and MIN_{AB}/MAX_{AB} of the QD film prepared by the nanocrystallines of Examples 1, 2, 4, 6 and 7 and Comparative example 1 were respectively calculated and recorded in Table 1. Data of a MIN_{AB}/MAX_{AB} column were calculated by converting the blue light absorbance a to the absorbance ABS₄₅₀ through a formula ABS₄₅₀=Ig[1/(1−a)]. The QD film prepared by the nanocrystalline of Example 1 was irradiated with blue light for 1224 hours at 450 nm. The QD film prepared by the nanocrystalline of Example 2 was irradiated with blue light for 1152 hours at 450 nm. The QD film prepared by the nanocrystalline of Example 4 was irradiated with blue light for 1104 hours at 450 nm. The QD film prepared by the nanocrystalline of Example 6 was irradiated with blue light for 1152 hours at 450 nm. The QD film prepared by the nanocrystalline of Example 7 was irradiated with blue light for 1320 hours at 450 nm. The QD film prepared by the nanocrystalline of Comparative example 1 was irradiated with blue light for 480 hours at 450 nm. Table 1 and FIG. 4 to FIG. 7 show that the nanocrystalline of the disclosure has desirable stability.

TABLE 1

| | (MAX_{PL} − | (MAX_{FWHM} − | MIN_{QY}/ | MIN_{AB}/ |
|---|---|---|---|---|
| No. | MIN_{PL})/nm | MIN_{FWHM})/nm | MAX_{QY} | MAX_{AB} |
| Example 1 | 2 | 2 | 94.0% | 97.4% |
| Example 2 | 1 | 2 | 87.4% | 98.3% |
| Example 4 | 2 | 3 | 90.8% | 97.7% |
| Example 6 | 0 | 2 | 91.1% | 96.5% |
| Example 7 | 1 | 3 | 87.1% | 90.5% |
| Comparative | 10 | 7 | 2.4% | 96.3% |
| example 1 | | | | |

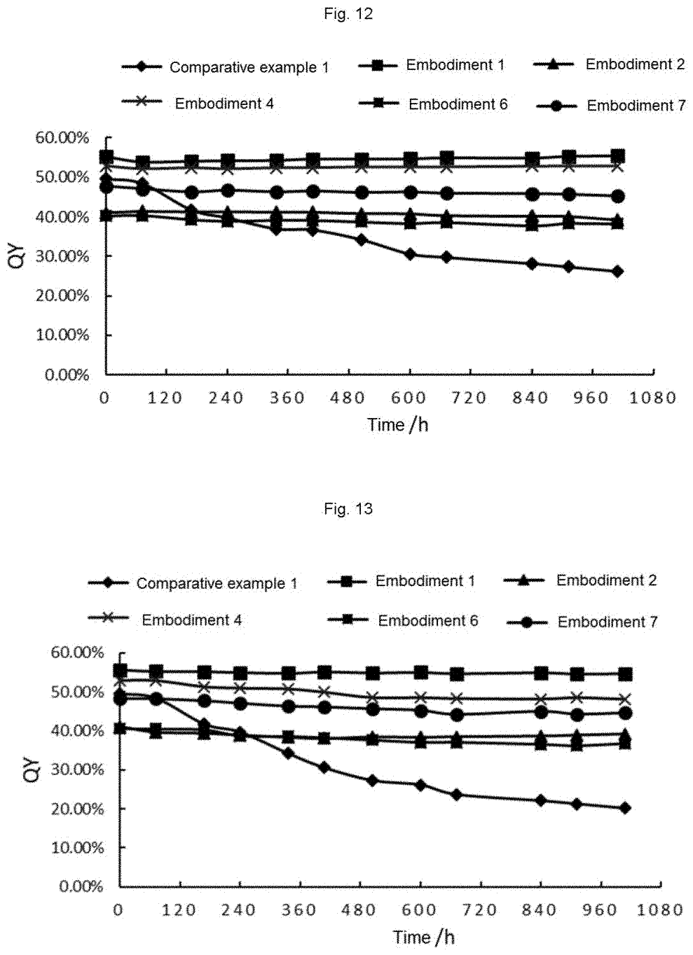

In addition, aging tests were respectively performed on the QD films prepared in Example 10 and Comparative example 2 under high-temperature and high-humidity (65° C., 95%) and high-temperature (85° C.) storage conditions. The QY of the QD film was measured by using the integrating sphere, and the measured data were respectively made into line charts for comparison, referring to FIG. 12 and FIG. 13. It may be seen from the figure that, the stability of the QD films prepared by the nanocrystallines of Examples 1, 2, 4, 6 and 7 of the disclosure was obviously better than that of Comparative example 1. Furthermore, the T₉₀ of the QD film prepared by the nanocrystallines of Examples 1, 2, 4, 6 and 7 under high-temperature and high-humidity (65° C., 95%) and high-temperature (85° C.) storage conditions exceeds 1000 hours. The T₉₀ of the QD film prepared by the nanocrystalline of Comparative example 1 under high-temperature and high-humidity (65° C., 95%) and high-temperature (85° C.) storage conditions was less than 168 hours.

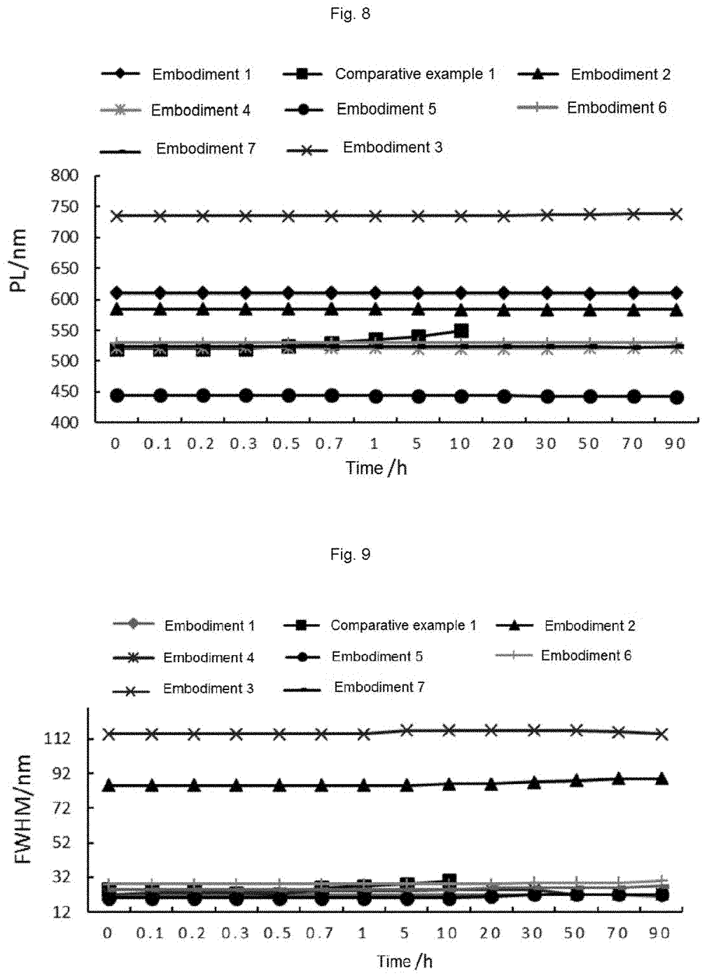

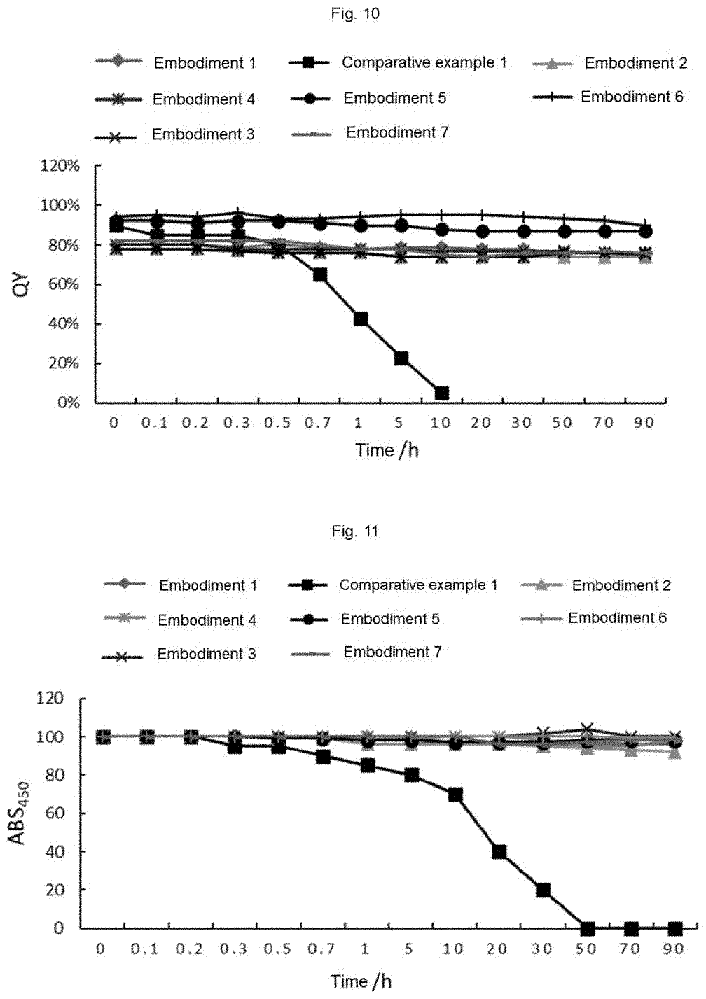

The nanocrystallines prepared in Examples 1 to 7 and Comparative example 1 were respectively dissolved in N,N-dimethylformamide (DMF) to prepare a nanocrystalline solution. 3 mL of the nanocrystalline solution was separately put into eight transparent cuvettes, and then 0.4 mL of 0.2M hydrochloric acid or 0.1 mL of a 3 Wt. % H₂O₂ aqueous solution was separately added into the eight cuvettes as an etchant (the etchant added in the eight cuvettes was the same). The ultraviolet absorption spectrum, fluorescence emission spectrum and QY of the nanocrystalline solution were monitored in real time at room temperature, and recorded respectively at 0, 0.1 min, 0.2 min, 0.3 min, 0.5 min, 0.7 min, 1 min, 5 min, 10 min, 20 min, 30 min, 50 min, 70 min, and 90 min. then, the recorded data were respectively made into line charts for comparison. FIG. 8, FIG. 9, FIG. 10 and FIG. 11 respectively show comparison line charts of changes in the fluorescence emission peak wavelength, full width at half maximum, QY and absorbance of the nanocrystallines of Comparative example 1 and Examples 1 to 7 during chemical etching. Since the QY of the nanocrystalline of Comparative example 1 was reduced to 5% when the nanocrystalline was chemically etched for 10 min, the QY was not recorded after 10 min.

MAX_{PL}−MIN_{PL}, MAX_{FWHM}−MIN_{FWHM}, MIN_{QY}/MAX_{QY}, and MIN_{AB}/MAX_{AB} of the nanocrystallines of Examples 1 to 7 and Comparative example 1 during the chemical etching were respectively calculated, and recorded in Table 2. Etching time of Examples 1 to 7 was 90 min, and the etching time of Comparative example 1 was 10 min. Since the rate of chemical etching was faster than that of photoetching, data in Table 2 and FIG. 8 to FIG. 11 not only show that the nanocrystalline of the disclosure was well resistant to chemical etching, but also indicate that the nanocrystalline of the disclosure was well resistant to photoetching. However, the nanocrystalline of Comparative example 1 was large in shell layer thickness, but poor in resistance to etching and poor in stability.

TABLE 2

| | (MAX_{PL} − | (MAX_{FWHM} − | MIN_{QY}/ | MIN_{AB}/ |
|---|---|---|---|---|
| No. | MIN_{PL})/nm | MIN_{FWHM})/nm | MAX_{QY} | MAX_{AB} |
| Example 1 | 1 | 1 | 95.0% | 96.0% |
| Example 2 | 1 | 4 | 94.9% | 92.0% |
| Example 3 | 3 | 2 | 93.8% | 96.2% |
| Example 4 | 3 | 3 | 94.9% | 95.0% |
| Example 5 | 3 | 2 | 94.6% | 97.0% |
| Example 6 | 0 | 2 | 93.8% | 99.0% |
| Example 7 | 1 | 2 | 90.2% | 96.0% |
| Comparative | 30 | 8 | 5.6% | 70.0% |
| example 1 | | | | |

To sum up, in the disclosure, according to the principle that a nanocrystalline etching process and a nanocrystalline growth process are an opposite process, the nanocrystalline having a plurality of sacrificial sub-layers was designed. By controlling changes of the optical parameters of the intermediate nanocrystalline during the coating and growing of the plurality of sacrificial sub-layers as small as possible, the stability of a final nanocrystalline product was improved. Therefore, the stability and aging life of the QD film or the light emitting device were enhanced.

The above were only the preferred Examples of the disclosure and were not intended to limit the disclosure. For those skilled in the art, the disclosure might have various modifications and variations. Any modifications, equivalent replacements, improvements and the like made within the spirit and principle of the disclosure shall fall within the scope of protection of the disclosure.

1. A nanocrystalline, comprising an initial nanocrystalline and a sacrificial shell layer coated of the initial nanocrystalline, the sacrificial shell layer comprises n sacrificial sub-layers sequentially coated outward with the initial nanocrystalline as the center, and the n sacrificial sub-layers are of the same material or different materials; if the nanocrystalline is etched, at least a portion of the sacrificial shell layer is gradually consumed during the etching; fluorescence emission peak wavelength, full width at half maximum, quantum yield, and absorbance under excitation of an excitation light with a certain wavelength are measured m times during etching; and a maximum fluorescence emission peak wavelength and a minimum fluorescence emission peak wavelength in measurement results of m times are respectively set to be MAX_{PL} and MIN_{PL}; a maximum full width at half maximum and a minimum full width at half maximum respectively are MAX_{FWHM} and MIN_{FWHM}; a maximum quantum yield and a minimum quantum yield respectively are MAX_{QY} and MIN_{QY}; and maximum absorbance and minimum absorbance respectively are MAX_{AB} and MIN_{AB}, 0≤MAX_{PL}−MIN_{PL}≤10 nm, 0≤MAX_{FWHM}−MIN_{FWHM}≤10 nm, 80%≤MIN_{QY}/MAX_{QY}≤100%, and 80%≤MIN_{AB}/MAX_{AB}≤100%, and n and m are integers greater than or equal to 1.

2. The nanocrystalline according to claim 1, wherein 0≤MAX_{PL}−MIN_{PL}≤5 nm, and 0≤MAX_{FWHM}−MIN_{FWHM}≤5 nm.

3. The nanocrystalline according to claim 1, wherein m is an integer greater than or equal to 2; during the etching, a difference between the fluorescence emission peak wavelength of two adjacent measurements is [−2 nm, 2 nm]; a difference between the full width at half maximum of two adjacent measurements is [−2 nm, 2 nm]; a percentage change in quantum yield between two adjacent measurements is [−10, 10%]; and a percentage change in absorbance between two adjacent measurements is [−10%, 10%].

4. The nanocrystalline according to claim 1, wherein a material of the sacrificial shell layer is selected from one or more of ZnN, ZnS, AlSb, ZnP, InP, AlS, PbS, HgS, AgS, ZnInS, ZnAlS, ZnSeS, CdSeS, CuInS, CuGaS, CuAlS, AgInS, AgAlS, AgGaS, ZnInP, ZnGaP, CdZnS, CdPbS, CdHgS, PbHgS, CdZnPbS, CdZnHgS, CdInZnS, CdAlZnS, CdSeZnS, AgInZnS, CuInZnS, AgGaZnS, CuGaZnS, CuZnSnS, CuAlZnS, CuCdZnS, MnS, ZnMnS, ZnPbS, WS, ZnWS, CoS, ZnCoS, NiS, ZnNiS, InS, SnS, and ZnSnS.

5. The nanocrystalline according to claim 1, wherein a thickness of the sacrificial shell layer is 5-15 nm.

6. A method for preparing a nanocrystalline, comprising:
S1, preparing an initial nanocrystalline;
S2, coating a sacrificial shell layer outside the initial nanocrystalline at one time or in steps, wherein the formed sacrificial shell layer comprises n sacrificial sub-layers sequentially coated outward with the initial nanocrystalline as the center, respectively being the first sacrificial sub-layer, the second sacrificial sub-layer, . . . , the nth sacrificial sub-layer, wherein n is an integer greater than or equal to 1; an intermediate nanocrystalline with the first sacrificial sub-layer to the ith sacrificial sub-layer coated outside the initial nanocrystalline is denoted by an ith nanocrystalline, wherein a fluorescence emission peak wavelength of the ith nanocrystalline is PLᵢ, a full width at half maximum of the ith nanocrystalline is FWHMᵢ, a quantum yield of the ith nanocrystalline is QYᵢ, and absorbance under excitation of an excitation light with a certain wavelength is ABSᵢ; when i takes all integers of [1, n], a maximum fluorescence emission peak wavelength and a minimum fluorescence emission peak wavelength in the PLᵢ are respectively recorded as MAX_{PL} and MIN_{PL}; a maximum full width at half maximum and a minimum full width at half maximum in the FWHMᵢ are respectively recorded as MAX_{FWHM} and MIN_{FWHM}; a maximum quantum yield and a minimum quantum yield in the QYᵢ are respectively recorded as MAX_{QY} and MIN_{QY}; and maximum absorbance and minimum absorbance in the ABSᵢ, are respectively recorded as MAX_{AB} and MIN_{AB}, wherein 0≤MAX_{PL}−MIN_{PL}≤10 nm, 0≤MAX_{FWHM}−MIN_{FWHM}≤10 nm, 80%≤MIN_{QY}/MAX_{QY}≤100%, and 80%≤MIN_{AB}/MAX_{AB}≤100%.

7. The preparation method according to claim 6, wherein 0≤MAX_{PL}−MIN_{PL}≤5 nm, and 0≤MAX_{FWHM}−MIN_{FWHM}≤5 nm.

8. The preparation method according to claim 6, wherein a difference between the fluorescence emission peak wavelength of the (i−1)th nanocrystalline and the ith nanocrystalline is [−2 nm, 2 nm]; a difference between the full width at half maximum is [−2 nm, 2 nm]; a percentage change in the quantum yield is [−10%, 10%]; and a percentage change in the absorbance is [−10%, 10%].

9. The preparation method according to claim 6, wherein the method for coating the ith sacrificial sub-layer in S2 comprises: mixing the initial nanocrystalline or the (i−1)th nanocrystalline, one or more cationic precursors configured to form the ith sacrificial sub-layer, one or more anion precursors configured to form the ith sacrificial sub-layer, and a solvent for reaction, and obtaining the ith nanocrystalline coated with the ith sacrificial sub-layer after the reaction.

10. The preparation method according to claim 6, wherein the method for coating the ith sacrificial sub-layer in S2 comprises: mixing the initial nanocrystalline or the (i−1)th nanocrystalline, one or more cationic precursors configured to form the ith sacrificial sub-layer, one or more anion precursors configured to form the ith sacrificial sub-layer, and a solvent for reaction for a certain period of time, then adding a doping agent containing a doping element to continue the reaction, and obtaining the ith nanocrystalline coated with the ith sacrificial sub-layer after the reaction.

11. The preparation method according to claim 6, wherein the method for coating the ith sacrificial sub-layer in S2 comprises: mixing the initial nanocrystalline or the (i−1)th nanocrystalline, one or more cationic precursors configured to form the ith sacrificial sub-layer, one or more anion precursors configured to form the ith sacrificial sub-layer, and a solvent in a container for reaction; when the fluorescence emission peak wavelength of products in the container is blue-shifted in two adjacent monitoring, adding a first cationic precursor to the container at least once; and when the fluorescence emission peak wavelength of the product in the container is red-shifted in two adjacent monitoring, adding a second cationic precursor to the container at least once, obtaining the ith nanocrystalline coated with the ith sacrificial sub-layer after the reaction.

12. The preparation method according to claim 11, wherein first cation of the first cationic precursor is able to red-shift the fluorescence emission peak wavelength of the nanocrystalline; second cation of the second cationic precursor is able to blue-shift the fluorescence emission peak wavelength of the nanocrystalline.

13. The preparation method according to claim 6, wherein a material of the sacrificial sub-layer is selected from one or more of ZnN, ZnS, AlSb, ZnP, InP, AlS, PbS, HgS, AgS, ZnInS, ZnAlS, ZnSeS, CdSeS, CuInS, CuGaS, CuAlS, AgInS, AgAlS, AgGaS, ZnInP, ZnGaP, CdZnS, CdPbS, CdHgS, PbHgS, CdZnPbS, CdZnHgS, CdInZnS, CdAlZnS, CdSeZnS, AgInZnS, CuInZnS, AgGaZnS, CuGaZnS, CuZnSnS, CuAlZnS, CuCdZnS, MnS, ZnMnS, ZnPbS, WS, ZnWS, CoS, ZnCoS, NiS, ZnNiS, InS, SnS, and ZnSnS.

14. The preparation method according to claim 6, wherein a total thickness of the first sacrificial sub-layer to the nth sacrificial sub-layer is 5-15 nm.

15. A composition, comprising the nanocrystalline according to claim 1.

16. An optical film, comprising a stacked first base material layer, light emitting layer and second base material layer, wherein the light emitting layer comprises the composition according to claim 15.

17. The optical film according to claim 16, not comprising a water-oxygen barrier film, wherein a Water Vapor Transmission Rate (WVTR) of the water-oxygen barrier film does not exceed 1 g/m²·24 h, and an Oxygen Transmission Rate (OTR) does not exceed 1 cm³/m²·24 h·0.1 Mpa.

18. The optical film according to claim 16, wherein T₉₀ of the optical film under a blue light accelerated aging condition is greater than 1000 hours; and the blue light accelerated aging condition comprises an ambient temperature being 70° C., blue light intensity being 150 mW/cm², and a blue light wavelength is 430-480 nm.

19. A light emitting device, comprising the nanocrystalline according to claim 1.
